(19) United States
(12) Patent Application Publication
(10) Pub. No.: US 2025/0331328 A1
(43) Pub. Date: Oct. 23, 2025

(54) IMAGE SENSOR

(71) Applicant: SAMSUNG ELECTRONICS CO., LTD., Suwon-si (KR)

(72) Inventors: Hakjin Lee, Suwon-si (KR); Jieun Kim, Suwon-si (KR); Keosung Park, Suwon-si (KR); Jiwon Seo, Suwon-si (KR); Yeojin Lee, Suwon-si (KR); Younggu Jin, Suwon-si (KR)

(73) Assignee: SAMSUNG ELECTRONICS CO., LTD., Suwon-si (KR)

(21) Appl. No.: 18/920,520

(22) Filed: Oct. 18, 2024

(30) Foreign Application Priority Data
Apr. 18, 2024 (KR) 10-2024-0052204

(51) Int. Cl. H01L 27/146

(52) U.S. Cl. CPC H10F 39/811; H10F 39/802; H10F 39/809; H10F 39/018

(57) ABSTRACT

An image sensor includes: a substrate including a plurality of photoelectric conversion regions; capacitor structures on the substrate; a capacitor insulating layer in a spacing between the capacitor structures; and external via structures in the spacing between the capacitor structures and penetrating the capacitor insulating layer. The capacitor structures include: conductive plate layers stacked and spaced apart from each other in a first direction perpendicular to an upper surface of the substrate; capacitor dielectric layers alternately stacked with the conductive plate layers; a first via structure penetrating the conductive plate layers, spaced apart from odd-numbered conductive plate layers, and in lateral contact with even-numbered the conductive plate layers; and a second via structure spaced apart from the first via structure, penetrating the conductive plate layers, spaced apart from the even-numbered conductive plate layers, and in lateral contact with the odd-numbered the conductive plate layers.

### CROSS-REFERENCE TO RELATED APPLICATION

This application claims benefit of priority to Korean Patent Application No. 10-2024-0052204, filed on Apr. 18, 2024, in the Korean Intellectual Property Office, the disclosure of which is incorporated herein by reference in its entirety.

### BACKGROUND

### 1. Field

Example embodiments of the present disclosure relate to an image sensor.

### 2. Brief Description of Related Art

An image sensor is a semiconductor-based sensor which may generate an electrical signal by receiving light, and may include a pixel array having a plurality of pixels and a logic circuit for driving the pixel array and generating an image. Each of the pixels may include a photodiode and a pixel circuit for converting an electrical charge generated by the photodiode into an electrical signal. As the number of pixels included in an image sensor has increased and a size of each pixel has decreased, various methods for effectively forming elements disposed on each pixel and providing a pixel circuit have been suggested.

### SUMMARY

According to example embodiments of the present disclosure, an image sensor is provided that may assure capacitance by optimizing the arrangement of a capacitor and a via in a pixel including the capacitor.

According to example embodiments of the present disclosure, an image sensor is provided and includes: a substrate including a plurality of photoelectric conversion regions to correspond to a plurality of pixels, respectively; a plurality of capacitor structures on the substrate; a capacitor insulating layer in a spacing between the plurality of capacitor structures; and external via structures in the spacing between the plurality of capacitor structures and penetrating the capacitor insulating layer, wherein each of the plurality of capacitor structures comprises: conductive plate layers stacked and spaced apart from each other in a first direction perpendicular to an upper surface of the substrate; capacitor dielectric layers alternately stacked with the conductive plate layers; a first via structure penetrating the conductive plate layers, spaced apart from odd-numbered ones of the conductive plate layers in a positional order, and in lateral contact with even-numbered ones of the conductive plate layers in the positional order; and a second via structure spaced apart from the first via structure, penetrating the conductive plate layers, spaced apart from the even-numbered ones of the conductive plate layers, and in lateral contact with the odd-numbered ones of the conductive plate layers, and wherein, in a plane view, the external via structures, the first via structure, and the second via structure are disposed on extension lines of diagonals of the conductive plate layers.

According to example embodiments of the present disclosure, an image sensor is provided and includes: a substrate including a plurality of photoelectric conversion regions to correspond to a plurality of unit pixel areas, respectively; interconnection structures on a first surface of the substrate and connected to the plurality of unit pixel areas; a plurality of capacitor structures on the interconnection structures, on the first surface of the substrate, such as to correspond to the plurality of unit pixel areas, respectively; a capacitor insulating layer in a spacing between the plurality of capacitor structures; and color filters and microlenses stacked on a second surface of the substrate, opposite of the first surface, wherein each of the plurality of capacitor structures comprises: a stack structure including conductive plate layers stacked and spaced apart from each other in a first direction perpendicular to the first surface of the substrate, and capacitor dielectric layers alternately stacked with the conductive plate layers; a first via structure penetrating the stack structure, spaced apart from odd-numbered ones of the conductive plate layers in a positional order, and in lateral contact with even-numbered ones of the conductive plate layers in the positional order; and a second via structure spaced apart from the first via structure, penetrating the stack structure, spaced apart from the even-numbered ones of the conductive plate layers, and in lateral contact with the odd-numbered ones of the conductive plate layers, and wherein the first via structure and the second via structure are disposed on diagonals of the conductive plate layers.

According to example embodiments of the present disclosure, an image sensor is provided and includes: a substrate; a pixel array including a plurality of pixels arranged in a direction parallel to a first surface of the substrate, wherein each of the plurality of pixels includes at least one photodiode in the substrate, a color filter on a second surface of the substrate opposite to the first surface, and at least one element on the first surface; a plurality of capacitor structures on the substrate such as to correspond to the plurality of pixels, respectively; a capacitor insulating layer in a spacing between the plurality of capacitor structures; external via structures in the spacing between the plurality of capacitor structures and penetrating the capacitor insulating layer; and a logic circuit configured to obtain a pixel signal from the plurality of pixels, wherein each of the plurality of capacitor structures includes: conductive plate layers stacked and spaced apart from each other in a first direction perpendicular to the first surface of the substrate; capacitor dielectric layers alternately stacked with the conductive plate layers; a first via structure penetrating the conductive plate layers, spaced apart from odd-numbered ones of the conductive plate layers in a positional order, and in lateral contact with even-numbered ones of the conductive plate layers in the positional order; and a second via structure spaced apart from the first via structure, penetrating the conductive plate layers, spaced apart from the even-numbered ones of the conductive plate layers, and in lateral contact with the odd-numbered ones of the conductive plate layers, and wherein, in a plane view, the external via structures, the first via structure, and the second via structure are disposed on extension lines of diagonals of the conductive plate layers.

### BRIEF DESCRIPTION OF DRAWINGS

The above and other aspects, features, and advantages of example embodiments of the present disclosure will be more clearly understood from the following detailed description, taken in combination with the accompanying drawings, in which:

FIG. 1 is a block diagram illustrating an image sensor according to an example embodiment of the present disclosure;

FIG. 2 is a circuit diagram illustrating a pixel circuit according to an example embodiment of the present disclosure;

FIG. 3 is a diagram illustrating the arrangement of pixels of an image sensor illustrated in FIG. 2;

FIG. 4A is an enlarged diagram illustrating a region A illustrated in FIG. 3, and FIG. 4B illustrates only a storage capacitor structure;

FIG. 5 is cross-sectional diagrams illustrating a cross-section of one of pixels illustrated in FIG. 4A;

FIGS. 6A to 6C are enlarged diagrams illustrating a portion of the example illustrated in FIG. 5;

FIGS. 7 to 9 are enlarged diagrams illustrating a capacitor structure of an image sensor according to an example embodiment of the present disclosure;

FIGS. 10 and 11 are cross-sectional diagrams illustrating a cross-section of an image sensor according to an example embodiment of the present disclosure; and

FIGS. 12A to 12E are cross-sectional diagrams illustrating a method of manufacturing an image sensor illustrated in FIG. 5.

### DETAILED DESCRIPTION

Hereinafter, non-limiting example embodiments of the present disclosure will be described as follows with reference to the accompanying drawings.

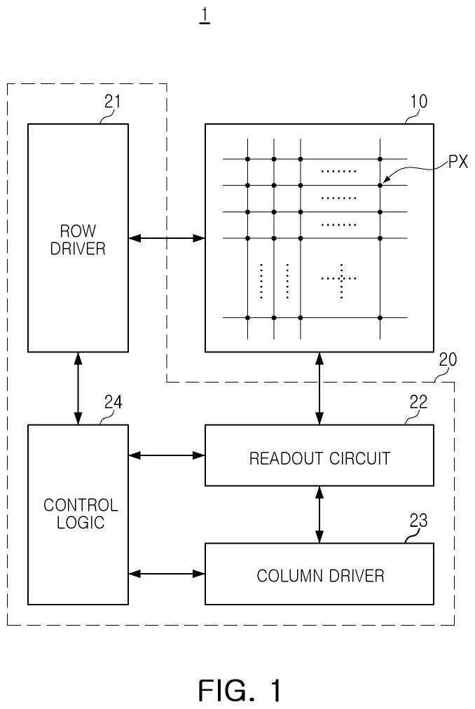

FIG. 1 is a block diagram illustrating an image sensor according to an example embodiment.

Referring to FIG. 1, an image sensor 1 may include a pixel array 10 and a logic circuit 20.

The pixel array 10 may include a plurality of pixels PX disposed in an array form along a plurality of rows and a plurality of columns. Each of the plurality of pixels PX may include at least one photoelectric conversion element generating charges in response to light, and a pixel circuit generating a pixel signal corresponding to charges generated by the photoelectric conversion element. The photoelectric conversion element may include a photodiode formed of a semiconductor material, and/or an organic photodiode formed of an organic material.

For example, the pixel circuit may include a floating diffusion, a transfer transistor, a reset transistor, a drive transistor, and a select transistor. In example embodiments, the configuration of the pixels PX may be varied. For example, each of the pixels PX may include an organic photodiode including an organic material, or may be implemented as a digital pixel. When the pixels PX are implemented as a digital pixel, each of the pixels PX may include an analog-to-digital converter to output a digital pixel signal.

The logic circuit 20 may include circuits for controlling the pixel array 10. For example, the logic circuit 20 may include a row driver 21, a readout circuit 22, a column driver 23, and a control logic 24. The row driver 21 may drive the pixel array 10 in a unit of row lines. For example, the row driver 21 may generate a transfer control signal for controlling the transfer transistor of the pixel circuit, a reset control signal for controlling the reset transistor, and a select control signal for controlling the select transistor, and may input the signals to the pixel array 10 as in a unit of row line.

The readout circuit 22 may include a correlated double sampler (CDS) and an analog-to-digital converter (ADC). The correlated double samplers may be connected through pixels PX and column lines. The correlated double samplers may read pixel signals through column lines from the pixels PX connected to a row line selected by a row line select signal of the row driver 21. The analog-to-digital converter may convert the pixel signal detected by the correlated double sampler into a digital pixel signal and may transfer the signal to the column driver 23.

The column driver 23 may include a latch or buffer circuit which may temporarily store a digital pixel signal, and an amplifier circuit, and may process the digital pixel signal received from the readout circuit 22. The row driver 21, the readout circuit 22, and the column driver 23 may be controlled by the control logic 24. The control logic 24 may include a timing controller to control operation timings of the row driver 21, the readout circuit 22, and the column driver 23.

Among the pixels PX, pixels PX disposed in the same position in the horizontal direction may share the same column line. For example, the pixels PX disposed in the same position in the vertical direction may be simultaneously selected by the row driver 21 and may output the pixel signal through column lines. In an example embodiment, the readout circuit 22 may simultaneously obtain the pixel signal from the pixels PX selected by the row driver 21 through column lines. The pixel signal may include a reset voltage and a pixel voltage, and the pixel voltage may be a voltage in which charges generated in response to light in each of the pixels PX are reflected in the reset voltage.

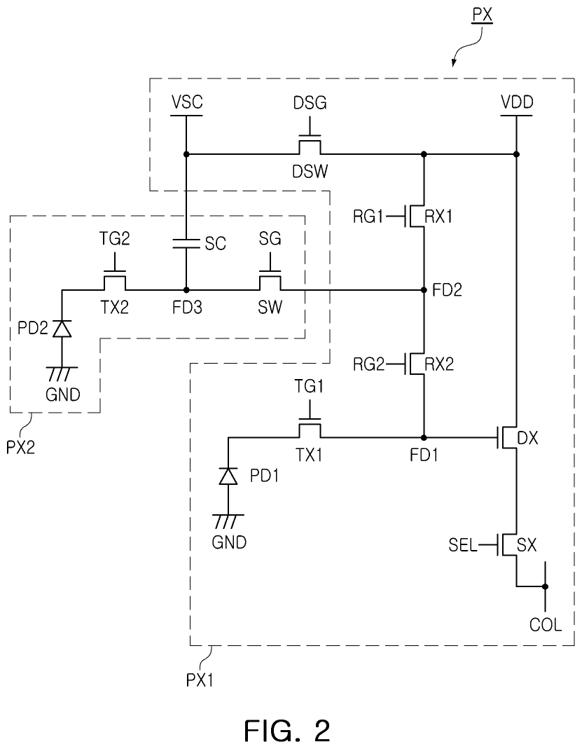

FIG. 2 is a circuit diagram illustrating a pixel circuit according to an example embodiment.

Referring to FIG. 2, a pixel circuit of the pixel PX of the image sensor 1 according to an example embodiment may include a first pixel circuit PX1 and a second pixel circuit PX2. The first pixel circuit PX1 may output an electrical signal using charges generated by at least one first photodiode PD1, and the second pixel circuit PX2 may output an electrical signal using charges generated by the second photodiode PD2. The operation of the active elements included in each of the first pixel circuit PX1 and the second pixel circuit PX2 may be controlled by a controller included in the image sensor.

The first pixel circuit PX1 may include a first reset transistor RX1, a second reset transistor RX2, at least one first transfer transistor TX1, a drive transistor DX, and a select transistor SX. The first photodiode PD1 may be connected to a first floating diffusion region FD1 through the first transfer transistor TX1.

The first transfer transistor TX1 may transfer charges accumulated in the first photodiode PD1 to the first floating diffusion region FD1 based on a first transfer control signal transferred from the row driver 21 to a first transfer gate structure TG1 of the first transfer transistor TX1. The first photodiode PD1 may generate electrons as main charge carriers. The drive transistor DX may operate as a source follower buffer amplifier by charges accumulated in the first floating diffusion region FD1. The drive transistor DX may amplify charges accumulated in the first floating diffusion region FD1 and may transfer charges to the select transistor SX.

The select transistor SX may operate by a select control signal input by the row driver 21 to a select gate structure SEL of the select transistor SX, and may perform switching and addressing operations. When the select control signal is applied from the row driver 21 to the select gate structure SEL, a voltage may be output to a column line COL connected to the select transistor SX. The voltage may be detected by a column driver 23 and a readout circuit 22 connected to the column line COL (see FIG. 1). The column driver 23 and the readout circuit 22 may detect a reset voltage when charges are not accumulated in the first floating diffusion region FD1 and may a detect pixel voltage when charges are accumulated in the first floating diffusion region FD1. In an example embodiment, the image sensor may generate an image by calculating a difference between the reset voltage and the pixel voltage.

The second pixel circuit PX2 may include a second transfer transistor TX2, a switch element SW, and a storage capacitor SC. The second photodiode PD2 may be connected to the switch element SW and the storage capacitor SC through the second transfer transistor TX2. Similarly to the first photodiode PD1, the second photodiode PD2 may also generate electrons as main charge carriers. Charges generated by the second photodiode PD2 may move to the storage capacitor SC when the second transfer transistor TX2 is turned on.

The storage capacitor SC may be an element for storing charges generated by the second photodiode PD2. The storage capacitor SC may be configured as a stacked-type capacitor and may be implemented as a metal-insulator-metal (MIM) capacitor, or a metal-insulator-metal (PIP) capacitor. A second power voltage VSC connected to the storage capacitor SC may be smaller than a first power voltage VDD of the entire pixel circuit (e.g., the pixel PX). However, an example embodiment thereof is not limited thereto. A discharge switch element DSW for applying the first power voltage VDD to a second power voltage node (corresponding to the second power voltage VSC) for discharging the storage capacitor SC may be further included.

The storage capacitor SC may store charges in response to the amount of charges generated by the second photodiode PD2 and operation of the second transfer transistor TX2. A third floating diffusion region FD3 may be further disposed between the second transfer transistor TX2 and the storage capacitor SC. A switch element SW may be connected between the third floating diffusion region FD3 and a second floating diffusion region FD2, and by operation of turning on and off of the switch element SW, charges of the storage capacitor SC may pass through the third floating diffusion region FD3 and may move to the second floating diffusion region FD2.

The second reset transistor RX2 may be connected between the second floating diffusion region FD2 and the first floating diffusion region FD1. That is, the second floating diffusion region FD2 may be connected to the first reset transistor RX1, the second reset transistor RX2, and the switching transistor SW. Charges accumulated in the second floating diffusion region FD2 may move to the first floating diffusion region FD1 in response to operation of the second reset transistor RX2.

In operation of the unit pixel circuit of the pixel PX, the first pixel circuit PX1 and the second pixel circuit PX2 may share at least a portion of circuit elements. For example, the second pixel circuit PX2 may use the drive transistor DX and the select transistor SX to output a pixel voltage corresponding to charges generated by the second photodiode PD2. Also, the first pixel circuit PX1 may use the second reset transistor RX2 and the second floating diffusion region FD2 to control a conversion gain of charges generated by the plurality of the first photodiode PD1 or the capacitance of the pixel.

In an example embodiment illustrated in FIG. 2, a plurality of the first photodiode PD1 and the second photodiode PD2 may share the column line COL. Accordingly, while the first pixel voltage corresponding to charges of the plurality of the first photodiode PD1 is output to the column line COL, the second photodiode PD2 may be isolated from the column line COL. For example, while the first pixel voltage is output to the column line COL, at least one from among the second reset transistor RX2 and the switch element SW may be turned off and may isolate the second photodiode PD2 from the column line COL. To generate the first pixel voltage using charges of the first photodiode PD1 and to output the voltage to the column line COL, the first transfer transistor TX1 may be turned on such that charges generated by the first photodiode PD1 may be accumulated in the first floating diffusion region FD1.

Similarly, while the second pixel voltage corresponding to charges of the second photodiode PD2 is output to the column line COL, the plurality of the first photodiode PD1 may be isolated from the column line COL. For example, while the second pixel voltage is output to the column line COL, the first transfer transistor TX1 may be turned off and may isolate the plurality of the first photodiode PD1 from the column line COL. To generate the second pixel voltage and output the voltage to the column line COL, the switch element SW and the second reset transistor RX2 may be turned on such that the third floating diffusion region FD3, the second floating diffusion region FD2, and the first floating diffusion region FD1 may be connected to each other. Charges generated by the second photodiode PD2 and stored in the storage capacitor SC may be accumulated in the first floating diffusion region FD1 and the second floating diffusion region FD2, and may be converted to a voltage by the drive transistor DX.

In an example embodiment, the second photodiode PD2 may be used to sense an external light source exhibiting flickering, or may be used to improve a dynamic range of the image sensor 1. To improve the dynamic range of the image sensor 1, when the first pixel voltage generated by charges of the plurality of the first photodiode PD1 is output multiple times, the second pixel voltage generated by charges of the second photodiode PD2 may be output only once.

An area of the first photodiode PD1 may be relatively larger than an area of the second photodiode PD2. In an example embodiment, charges generated by the second photodiode PD2 may be used to generate an image accurately representing an external light source exhibiting flickering, whereas charges generated by the plurality of the first photodiode PD1 may be used to generate a general image. Also, by controlling the exposure time for each of the first photodiode PD1 and the second photodiode PD2 to receive light and transmitting a voltage to the column line COL through a shuttering method, the dynamic range and image quality of the image sensor may be improved.

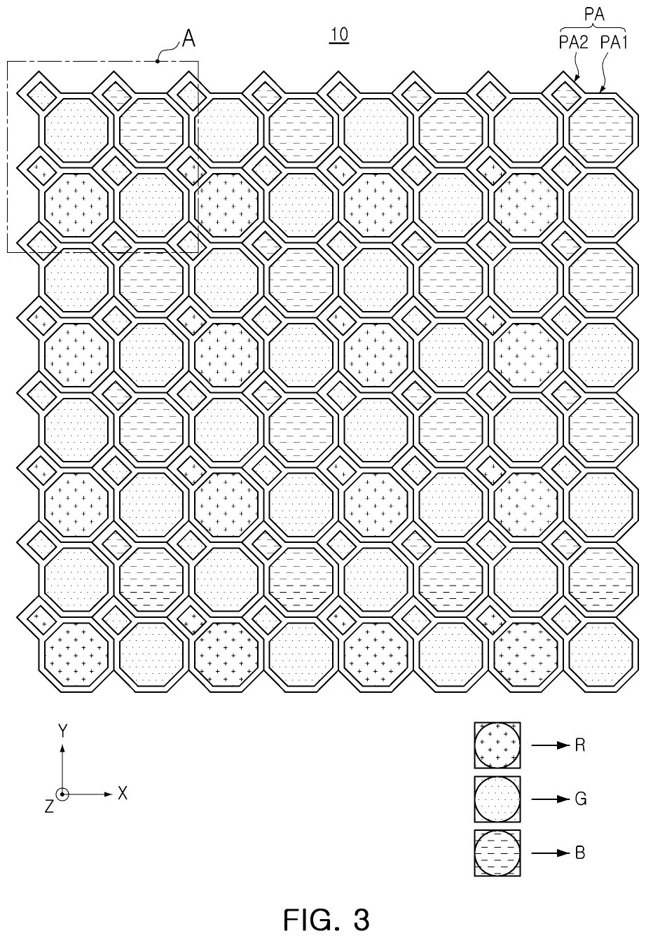

The pixel circuit of the pixel PX in FIG. 2 may be implemented as unit pixels having the same arrangement as in FIG. 3.

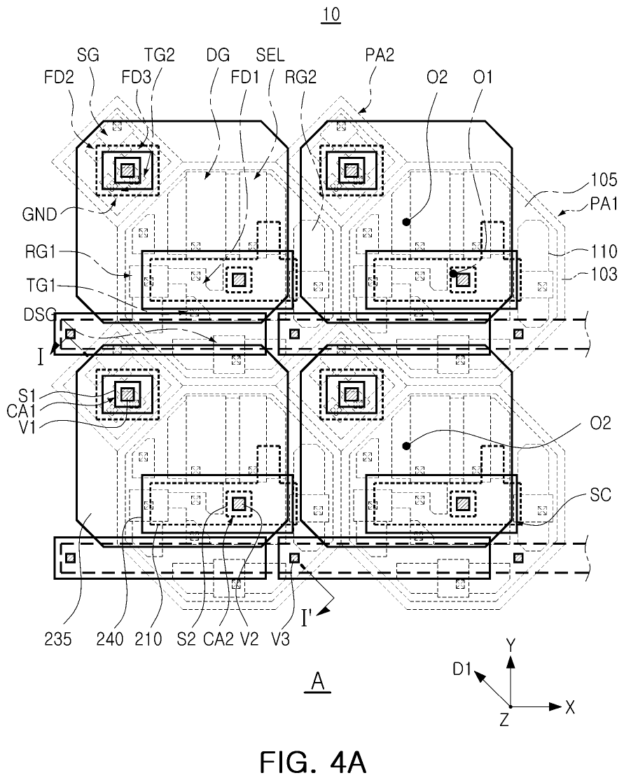

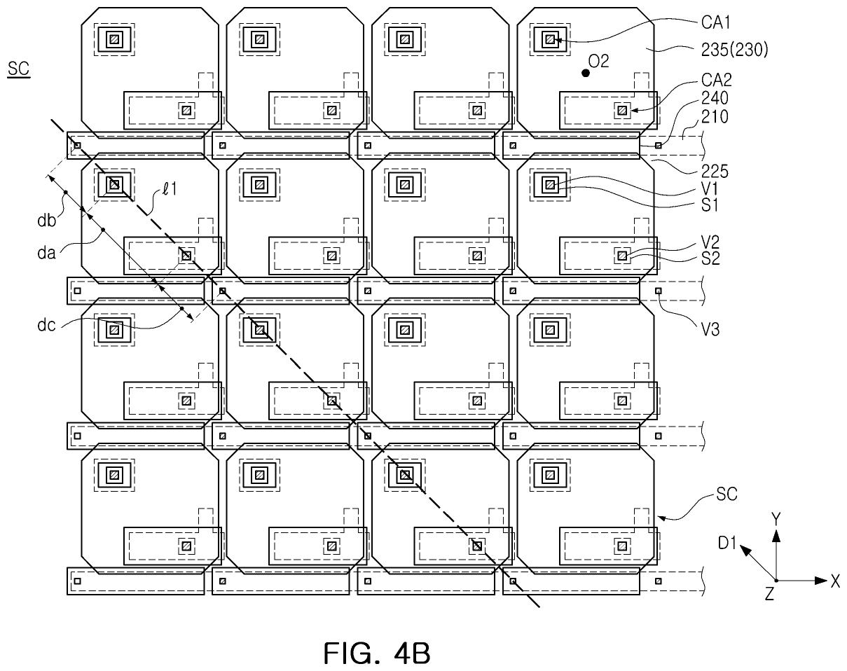

Referring to FIG. 3, the pixel array 10 of the image sensor 1 in an example embodiment may include a plurality of unit pixels of the pixel PX, and a pixel region PA assigned to each of the pixels PX may include a first pixel region PA1, corresponding to the first pixel circuit PX1 and a second pixel region PA2 corresponding to the second pixel circuit PX2. For example, the pixel array 10 may include a first pixel region PA1 corresponding to a general pixel and a second pixel region PA2 corresponding to an autofocus pixel. The position of the second pixel region PA2 and the arrangement thereof may be varied, and as illustrated in FIG. 2, the second pixel region PA2 may extend with a side surface of the first pixel region PA1. Specifically, when the first pixel region PA1 has a polygonal shape having a space therein (e.g., an octagonal shape), the second pixel region PA2 may be implemented to have a polygonal shape sharing one of the sides thereof. Accordingly, a pixel separator 103 (see FIG. 4A) may be disposed between the first pixel region PA1 and the second pixel region PA2, and the pixel separator 103 may surround the first pixel region PA1 and the second pixel region PA2. An area of the first pixel region PA1 may be larger than an area of the second pixel region PA2 and, accordingly, the first photodiode PD1 included therein may also have a size larger than that the size of the second photodiode PD2.

When the second pixel region PA2 extends to one surface of the first pixel region PA1, the second pixel region PA2 may have a slope in a diagonal (e.g., the direction D1 in FIG. 4A) direction rather than the X-direction or the Y-direction. Accordingly, the second pixel region PA2 may be disposed in a spacing between two neighboring ones of the first pixel regions PA1, but the position of the second pixel region PA2 is not limited to the example illustrated in FIG. 3 and may be varied.

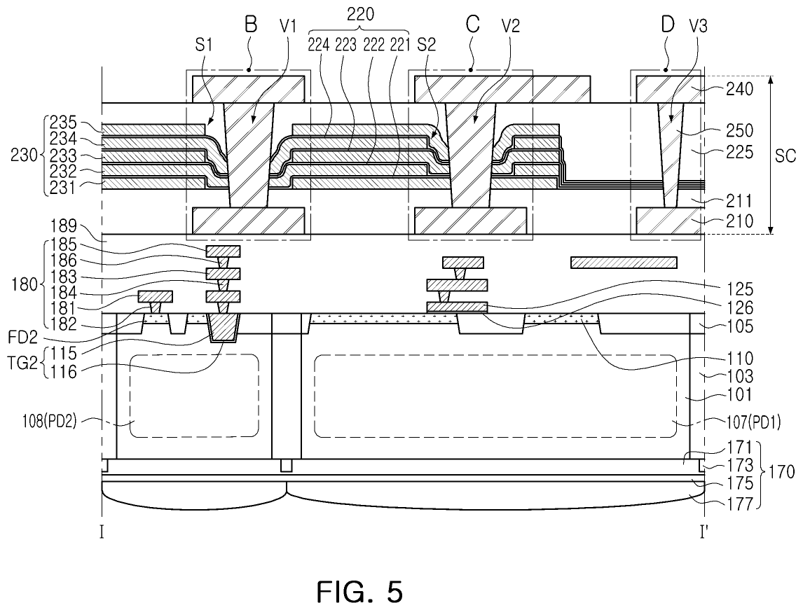

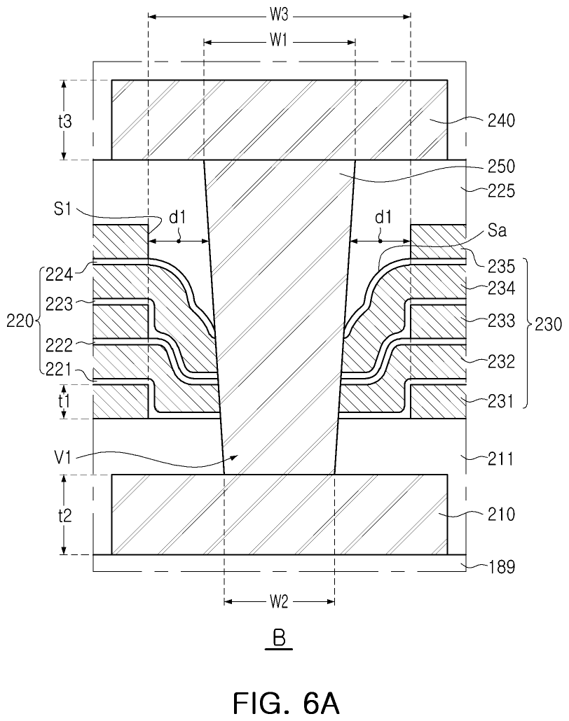

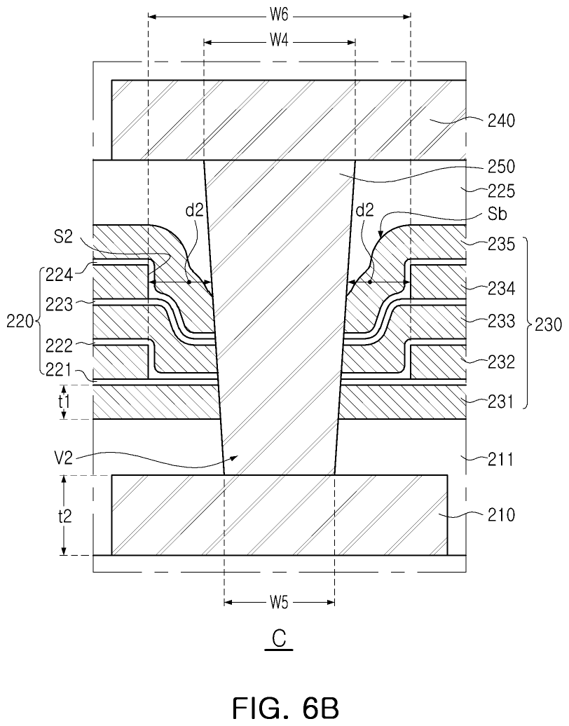

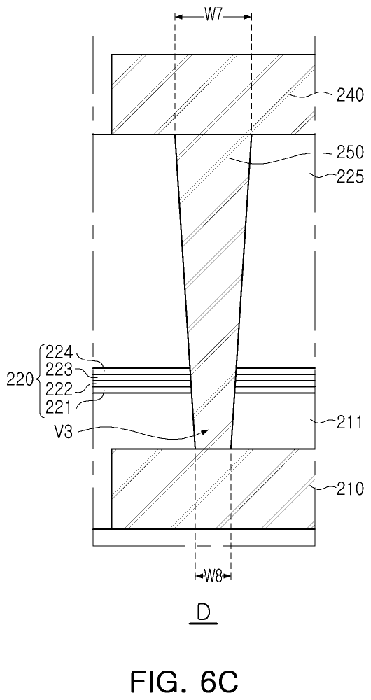

FIG. 4A is an enlarged diagram illustrating a region A of FIG. 3, and FIG. 4B illustrates only a storage capacitor structure. FIG. 5 is a cross-sectional diagrams illustrating a cross-section of one of the pixels illustrated in FIG. 4A. FIGS. 6A to 6C are enlarged diagrams illustrating a portion of the example illustrated in FIG. 5. In this case, FIG. 6A is an enlarged diagram illustrating a region B of FIG. 5, FIG. 6B is an enlarged diagram illustrating a region C of FIG. 5, and FIG. 6C is an enlarged diagram illustrating a region D of FIG. 5.

The pixel array 10 illustrated in FIG. 4A may correspond to the pixel array 10 illustrated in FIG. 3, and FIG. 4A illustrates 2×2 unit of the pixels PX included in the pixel array 10.

Referring to FIGS. 4A-6C, a pixel separator 103 may be disposed between pixel regions PA defining a unit of the pixels PX, and each of the pixel regions PA may include a first pixel region PA1 having a polygonal shape (e.g., an octagonal shape), and a second pixel region PA2 having a quadrangular shape sharing one side implemented by the pixel separator 103.

The first pixel region PA1 may occupy an area larger than an area of the second pixel region PA2, and the pixel regions (e.g., the first pixel region PA1 and the second pixel region PA2) may include floating diffusion regions (e.g., the first floating diffusion region FD1, the second floating diffusion region FD2, and the third floating diffusion region FD3), transfer gate structures (e.g., the first transfer gate structure TG1 and the second transfer gate structure TG2) and gate structures (e.g., a gate structure DG, the select gate structure SEL, a gate structure SG, a gate structure RG1, a gate structure RG2, a gate structure DSG, a gate structure 125, and a gate structure 126) of the plurality of transistors therein.

The floating diffusion regions (e.g., the first floating diffusion region FD1, the second floating diffusion region FD2, and the third floating diffusion region FD3) in each of the pixel regions (e.g., the first pixel region PA1 and the second pixel region PA2) may be doped with first conductivity-type impurities, and charges generated by photodiodes (e.g., the first photodiode 107 and the second photodiode 108 (see FIG. 5) may be accumulated in the regions. For example, the first conductivity-type impurities may be N-type impurities.

The floating diffusion regions (e.g., the first floating diffusion region FD1, the second floating diffusion region FD2, and the third floating diffusion region FD3) may be connected to at least one contact plug, and the floating diffusion regions (e.g., the first floating diffusion region FD1, the second floating diffusion region FD2, and the third floating diffusion region FD3) may be adjacent to the transfer gate structures (e.g., the first transfer gate structure TG1 and the second transfer gate structure TG2). The transfer gate structures (e.g., the first transfer gate structure TG1 and the second transfer gate structure TG2) may be adjacent to the first photodiode 107 and the second photodiode 108 formed on an inner side of the pixel separator 103 in the first direction (Z-direction).

When a first bias voltage is input to the first transfer gate structure TG1 and the second transfer gate structure TG2, charges generated by the first photodiode 107 and the second photodiode 108 may not move to the floating diffusion regions (e.g., the first floating diffusion region FD1, the second floating diffusion region FD2, and the third floating diffusion region FD3). When a voltage of the first transfer gate structure TG1 and the second transfer gate structure TG2 increases to a second bias voltage higher than the first bias voltage, charges generated by the first photodiode 107 and the second photodiode 108 may move to the floating diffusion regions (e.g., the first floating diffusion region FD1, the second floating diffusion region FD2, and the third floating diffusion region FD3). For example, the first bias voltage may be a negative voltage, and the second bias voltage may be a positive voltage. An absolute value of the first bias voltage may be smaller than an absolute value of the second bias voltage.

In an example embodiment illustrated in FIG. 4A, the floating diffusion regions (e.g., the first floating diffusion region FD1, the second floating diffusion region FD2, and the third floating diffusion region FD3) may extend in the second direction (X-direction) and/or the third direction (Y-axis direction). However, the shapes of the floating diffusion regions (e.g., the first floating diffusion region FD1, the second floating diffusion region FD2, and the third floating diffusion region FD3) are not limited as illustrated in FIG. 4A, and may be varied in example embodiments.

The first transfer gate structure TG1 of the first transfer transistor TX1 connected to the first photodiode (see, e.g., the first photodiode PD1 in FIG. 2, or the first photodiode 107 in FIG. 5) may be disposed in the first pixel region PA1, and the second transfer gate structure TG2 of the second transfer transistor TX2 connected to the second photodiode (see, e.g., the second photodiode PD2 in FIG. 2, or the second photodiode 108 in FIG. 5) may be disposed in the second pixel region PA2.

Among the transistors, a discharge switch element DSW, a reset transistor RX, a select transistor SX, and a drive transistor DX may be disposed in the first pixel region PA1, and a switch element SW may be disposed in the second pixel region PA2. The transistors may include gate structures 125 and 126, and active regions 110 disposed on both sides of the gate structures 125 and 126. An area of each of the active regions 110 may be smaller than areas of the floating diffusion regions (e.g., the first floating diffusion region FD1, the second floating diffusion region FD2, and the third floating diffusion region FD3), which may be because the areas of the floating diffusion regions (e.g., the first floating diffusion region FD1, the second floating diffusion region FD2, and the third floating diffusion region FD3) in which charges generated by each photodiode (e.g., the first photodiode 107 and the second photodiode 108) are accumulated may need to be relatively larger. An element separator 105 to isolate the active regions 110 may be further included.

Each of the pixel regions (e.g., the first pixel region PA1 and the second pixel region PA2) may further include an active region 110 for a ground region GND. The ground region GND may be isolated from the floating diffusion regions (e.g., the first floating diffusion region FD1, the second floating diffusion region FD2, and the third floating diffusion region FD3) and the transistors and may not be in contact with the transfer gate structures (e.g., the first transfer gate structure TG1 and the second transfer gate structure TG2). Also, the ground region GND may be doped with impurities having a second conductivity type different from that of the floating diffusion regions (e.g., the first floating diffusion region FD1, the second floating diffusion region FD2, and the third floating diffusion region FD3) and the active regions 110.

Contact plugs may be disposed in the transfer gate structures (e.g., the first transfer gate structure TG1 and the second transfer gate structure TG2), the floating diffusion regions (e.g., the first floating diffusion region FD1, the second floating diffusion region FD2, and the third floating diffusion region FD3), the gate structures 125 and 126, the active regions 110, and the ground region GND.

A substrate 101 may be provided and configured as a semiconductor substrate. For example, the substrate 101 may be formed of a semiconductor material (e.g., a single crystal silicon substrate).

The photodiodes (e.g., a first photodiode 107 and a second photodiode 108) may be formed in the substrate 101 in the two pixel regions (e.g., the first pixel region PA and the second pixel region PA2), respectively. The photodiodes (e.g., the first photodiode 107 and the second photodiode 108) may be adjacent to the respective transfer gate structures (e.g., the first transfer gate structure TG1 and the second transfer gate structure TG2) in the Z-direction perpendicular to one surface of the substrate 101.

An optical unit 170 may be disposed on one surface of the substrate 101 adjacent to the photodiodes (e.g., the first photodiode 107 and the second photodiode 108) in the Z-direction (e.g., the vertical direction). The optical unit 170 may include a color filter 171, a grid structure 173, a planarization layer 175, and a microlens 177. The color filter 171 may be isolated from the color filters of other adjacent pixels by the grid structure 173, and may transmit light in a predetermined wavelength band. The microlens 177 may refract light incident to the pixel 100 and may focus light on the first photodiode 107. The first photodiode 107 may generate charges in response to light passing through the optical unit 170.

The pixel regions (e.g., the first pixel region PA1 and the second pixel region PA2) may be disposed on the other surface of the substrate 101, which is one side of the photodiodes (e.g., the first photodiode 107 and the second photodiode 108), in the Z-direction (the first direction). Accordingly, the optical unit 170 and the pixel regions (e.g., the first pixel region PA1 and the second pixel region PA2) may be disposed on both sides of the photodiodes (e.g., the first photodiode 107 and the second photodiode 108) in the Z-direction (the first direction). As described above, the pixel regions (e.g., the first pixel region PA1 and the second pixel region PA2) may include the floating diffusion regions (e.g., the first floating diffusion region FD1, the second floating diffusion region FD2, and the third floating diffusion region FD3), and the transfer gate structures (e.g., the first transfer gate structure TG1 and the second transfer gate structure TG2) and transistors adjacent to the floating diffusion regions (e.g., the first floating diffusion region FD1, the second floating diffusion region FD2, and the third floating diffusion region FD3).

The gate electrode (e.g., the gate structure 125) of the transistors may include a semiconductor material, such as silicon, germanium, or a combination thereof. The gate electrode (e.g., the gate structure 125) may include an N-type or P-type doped layer, and may also include a non-doped layer.

The floating diffusion regions (e.g., the first floating diffusion region FD1, the second floating diffusion region FD2, and the third floating diffusion region FD3) may include a plurality of regions doped with impurities at different concentrations, but an example embodiment thereof is not limited thereto. When a plurality of regions are included, the doping may be at a higher concentration as a distance from the transfer gate structures (e.g., the first transfer gate structure TG1 and the second transfer gate structure TG2) increases.

The transfer gate structures (e.g., the first transfer gate structure TG1 and the second transfer gate structure TG2) may include a transfer gate electrode 115, a transfer gate insulating layer 116, and a transfer gate spacer. The transfer gate electrode 115 may be formed of a conductive material such as polysilicon, metal, or metal silicide, and the first bias voltage and the second bias voltage described above may be applied to the transfer gate electrode 115. The transfer gate insulating layer 116 may be disposed between the transfer gate electrode 115 and the substrate 101. The transfer gate electrode 115 may include a multilayer structure, and the multiple layers may have different shapes. For example, the lower electrode layer may be disposed between the upper electrode layer and the photodiodes (e.g., the first photodiode 107 and the second photodiode 108) in the first direction, and may have a width decreasing toward the photodiodes (e.g., the first photodiode 107 and the second photodiode 108). The lower electrode layer may be disposed on a level lower than a level of an upper surface of the substrate 101 and may be buried in the substrate 101, and the upper electrode layer may have a region disposed on a level higher than a level of the upper surface of the substrate 101. The transfer gate insulating layer 116 may be formed along an interfacial surface between the transfer gate electrode 115 and the substrate 101. A transfer gate spacer may be disposed between the floating diffusion regions (e.g., the first floating diffusion region FD1, the second floating diffusion region FD2, and the third floating diffusion region FD3) and the upper electrode layer.

Each of the gate structures (e.g., the gate structures 125 and 126) of the transistors, other than the transfer transistors (e.g., the first transfer transistor TX1 and the second transfer transistor TX2) may have a shape different from a shape of the transfer gate structures (e.g., the first transfer gate structure TG1 and the second transfer gate structure TG2). The gate structures 125 and 126 of the transistor may be formed on the substrate 101 and may include the gate electrode (e.g., the gate structure 125), the gate insulating layer (e.g., the gate structure 126), and a gate spacer.

In an example embodiment, the pixels PX may include an insulating liner. The insulating liner may be formed conformally on the other surface of the substrate 101. The insulating liner may conformally cover the gate structures (e.g., the first transfer gate structure TG1, the second transfer gate structure TG2, and a gate structure DG) and the substrate 101 in a lower portion on the gate structures (e.g., the first transfer gate structure TG1, the second transfer gate structure TG2, and the gate structure DG).

An interconnection region 180 may be disposed on the substrate 101. The interconnection region 180 may include a plurality of upper interconnections (e.g., first circuit interconnections 181, second circuit interconnections 183, and third circuit interconnections 185) connected to the gate electrodes (e.g., the gate structures 125) and the active regions 110 of the transfer gate structures (e.g., the first transfer gate structure TG1 and the second transfer gate structure TG2) and the transistors, and contact plugs (e.g., first plugs 182, second plugs 184, and third plugs 186) connecting the interconnections. In FIG. 5, the upper interconnections (e.g., the first circuit interconnections 181, the second circuit interconnections 183, and the third circuit interconnections 185) may form a three-layer structure, but an example embodiment thereof is not limited thereto. The contact plugs (e.g., the first plugs 182, the second plugs 184, and the third plugs 186) may include metal such as tungsten (W), aluminum (Al), or copper (Cu), and tungsten may be preferably used. The contact plugs may have a pillar shape and may have inclined side surfaces having a width decreasing toward the substrate 101.

The interconnection region 180 may be formed in an intermetallic insulating layer 189 formed on the substrate 101. By the interconnection region 180, the floating diffusion regions (e.g., the first floating diffusion region FD1, the second floating diffusion region FD2, and the third floating diffusion region FD3), the transfer gate structures (e.g., the first transfer gate structure TG1 and the second transfer gate structure TG2), and the transistors included in the pixel region PA may be electrically connected to each other. The intermetallic insulating layer 189 may include a single film or a multi-film structure of at least one from among a silicon oxide film (SiO), a silicon nitride film (SiN), a silicon nitride film (SiON), and a porous low dielectric film.

In an example embodiment, each of the units of the pixels PX may include a storage capacitor structure implementing a storage capacitor SC of a pixel circuit, and the storage capacitor SC (also referred to as the storage capacitor structure) may be disposed on the intermetallic insulating layer 189 on the substrate 101.

As illustrated in FIGS. 4A and 4B, the storage capacitors SC may have a predetermined spacing distance on the intermetallic insulating layer 189 and may form columns and rows. Each of the storage capacitors SC may be provided in a state in which capacitor electrode layers 230 (e.g., plate-type capacitor electrode layers) having a predetermined area are stacked to correspond to the pixel PX, respectively. The storage capacitor SC may partially overlap the pixel region PA of the corresponding pixel PX in the Z-direction, but may not be completely included in the pixel region PA. When a center of the first pixel region PA1 occupying most of the pixel region PA is defined as a first node O1, a center of the storage capacitor SC may be defined as a second node O2. The first node O1 and the second node O2 may be partially offset in the Z-direction and may not be disposed linearly. The storage capacitor SC may simultaneously overlap the first pixel region PA1 and the second pixel region PA2.

The storage capacitor SC may include a lower interconnection structure 210 on the intermetallic insulating layer 189, a plurality of capacitor electrode layers 230 on the lower interconnection structure 210, an upper interconnection structure 240 on the plurality of capacitor electrode layer 230, and a plurality of via structures (e.g., a first via structure V1 and a second via structure V2) selectively in contact with a portion of the plurality of capacitor electrode layers 230 between the lower interconnection structure 210 and the upper interconnection structure 240.

The plurality of capacitor electrode layers 230 occupying the entire area of the storage capacitor SC may form 3 to 10 layers, preferably 5 to 7 layers.

Each of the capacitor electrode layers 230 may be disposed parallel to an upper surface of the substrate 101, and may have a plate-type in which side surfaces thereof are patterned in parallel to have the same shape having the same area. By alternately stacking capacitor dielectric layers 220 between the capacitor electrode layers 230 such that the capacitor electrode layers 230 are spaced apart from each other in the Z-direction perpendicular to the upper surface of the substrate 101, a stack structure may be formed.

The capacitor electrode layers 230 may have a quadrangular shape (e.g., a rectangular shape or a square shape), and chamfering may be performed at each corner to remove a tip, thereby forming an overall octagonal shape. Alternatively, chamfering may be performed such that each corner may have a curved surface, but an example embodiment thereof is not limited thereto.

Each of the capacitor electrode layers 230 may have the same thickness and may have a first thickness t1. The first thickness t1 may be equal to or greater than a thickness of each of the upper interconnections (e.g., the first circuit interconnections 181, the second circuit interconnections 183, and the third circuit interconnections 185), but an example embodiment thereof is not limited thereto.

Each of the capacitor electrode layers 230 may include at least one from among a high melting point metal film such as cobalt, titanium, nickel, tungsten and molybdenum, and/or a metal nitride film such as titanium nitride film (TiN), titanium silicon nitride film (TiSiN), titanium aluminum nitride film (TiAlN), tantalum nitride film (TaN), tantalum silicon nitride film (TaSiN), tantalum aluminum nitride film (TaAlN) tungsten nitride film (WN), and combinations thereof, but an example embodiment thereof is not limited thereto.

The capacitor dielectric layers 220 between the capacitor electrode layers 230 may have the same thickness and a thickness smaller than the first thickness t1 of the capacitor electrode layer 230, and a thickness smaller than the first thickness t1 of the capacitor electrode layer 230, and may function as a dielectric layer between the capacitor electrode layer 230 in a lower portion and the capacitor electrode layer 230 in an upper portion and may form a capacitor.

The plurality of capacitor dielectric layers 220 may include the same material, and may include at least one from among metal oxide such as HfO₂, ZrO₂, Al₂O₃, La₂O₃, Ta₂O₃ and TiO₂, a dielectric material having perovskite structures such as SrTiO₃(STO), (Ba,Sr)TiO₃(BST), BaTiO₃, PZT, PLZT, and a combination thereof, but an example embodiment thereof is not limited thereto. Each of the capacitor dielectric layers 220 may be configured as a single film or multiple films.

Each of the storage capacitors SC may include a first connection region CA1 penetrated by and connected to the first via structure V1, and a second connection region CA2 spaced apart from the first connection region CA1, and penetrated by and connected to the second via structure V2.

The capacitor electrode layers 230 may include at least one opening region (e.g., a first opening region S1 and a second opening region S2) penetrated by the via structures (e.g., the first via structure V1 and the second via structure V2) in the first connection region CA1 and the second connection region CA2.

The opening regions (e.g., the first opening region S1 and the second opening region S2) may be disposed one by one for each of the capacitor electrode layers 230, and the opening regions (e.g., the first opening region S1 and the second opening region S2) may alternately overlap the capacitor electrode layers 230.

As an example, the first capacitor electrode layer 231 disposed on a lowermost end of the capacitor electrode layers 230 may include the first opening region S1 penetrated by the first via structure V1, the second capacitor electrode layer 232 thereon may not include the first opening region S1, and the third capacitor electrode layer 233 may include a first opening region S1 overlapping with the first opening region S1 of the first capacitor electrode layer 231 in the Z-direction.

As described above, in the first connection region CA1 penetrated by the first via structure V1, the first opening region S1 may be disposed on odd-numbered electrode layers, which may be the first capacitor electrode layer 231, the third capacitor electrode layer 233 and the fifth capacitor electrode layer 235. The second capacitor electrode layer 232 and the fourth capacitor electrode layer 234 disposed therebetween may not include the first opening region S1.

In the second connection region CA2 penetrated by the second via structure V2, the second opening region S2 may be disposed on the second capacitor electrode layer 232 and the fourth capacitor electrode layer 234, which are even-numbered electrode layers, and the first capacitor electrode layer 231, the third capacitor electrode layer 233, and the fifth capacitor electrode layer 235 in the region overlapping with the second opening region S2 penetrated by the second via structure V2 may not include the second opening region S2.

The first opening region S1 and the second opening region S2 may be defined as openings which may be extended to open the capacitor electrode layer 230 to have an area larger than the area of the first via structure V1 and the second via structure V2 to be penetrated, such that sidewalls of the first opening region S1 and the second opening region S2 and the via structures (e.g., the first via structure V1 and the second via structure V2) are not in direct contact with each other and spaced apart from each other and a spacing therebetween may be filled with an insulating material.

The sizes of the first opening region S1 and the second opening region S2 may be the same, the side surfaces of the first opening region S1 and the second opening region S2 in the capacitor electrode layers 230 may be aligned in the Z-direction, and when a side surface of the first via structure V1 has a slope, the distance from the side surface of the first opening region S1 and the second opening region S2 to the sloped surface of the first via structure V1 may decrease upwardly.

Similarly, in the first connection region CA1 penetrated by the first via structure V1, odd-numbered electrode layers (e.g., the first capacitor electrode layer 231, the third capacitor electrode layer 233, and the fifth capacitor electrode layer 235) may include the first opening region S1, and even-numbered electrode layers (e.g., the second capacitor electrode layer 232 and the fourth capacitor electrode layer 234) may cover the first opening region S1 of the capacitor electrode layer 230 below without the first opening region S1 and may have a shape recessed inwardly toward the substrate 101. In the second connection region CA2 penetrated by the second via structure V2, even-numbered electrode layers (e.g., the second capacitor electrode layer 232 and the fourth capacitor electrode layer 234) may include a second opening region S2, and odd-numbered electrode layers (e.g., the first capacitor electrode layer 231, the third capacitor electrode layer 233, and the fifth capacitor electrode layer 235) may cover the second opening region S2 of the capacitor electrode layer 230 below without the second opening region S2, and may have a shape recessed inwardly toward the substrate 101.

The capacitor dielectric layer 220 may be conformally coated and disposed on each of the capacitor electrode layers 230, may extend along the side surfaces of the first opening region S1 and the second opening region S2, may be in contact with the capacitor dielectric layer 220 in the lower portion, and may have a shape recessed inwardly toward the substrate 101.

Accordingly, in the first connection region CA1, the first dielectric layer 221 may be disposed on the intermetallic insulating layer 189 along the first opening region S1 of the first capacitor electrode layer 231, the second capacitor electrode layer 232 may be recessed inwardly thereon, and the second dielectric layer 222 may be disposed conformally thereon. When the first opening region S1 of the third capacitor electrode layer 233 overlaps and exposes the second dielectric layer 222 below, the third dielectric layer 223 may extend from an upper surface of the third capacitor electrode layer 233 along a side surface of the first opening region S1 and may extend to the upper surface of the second dielectric layer 222. The fourth capacitor electrode layer 234 may be inwardly recessed thereon, the fourth dielectric layer 224 may be conformally disposed thereon, and the first opening region S1 of the fifth capacitor electrode layer 235 may expose the fourth dielectric layer 224.

Similarly, in second connection region CA2 penetrated by the second via structure V2, even-numbered electrode layers (e.g., the second capacitor electrode layer 232 and the fourth capacitor electrode layer 234) may include a second opening region S2, and odd-numbered electrode layers (e.g., the first capacitor electrode layer 231, the third capacitor electrode layer 233, and the fifth capacitor electrode layer 235) may cover the second opening region S2 of the second capacitor electrode layer 232 and the fourth capacitor electrode layer 234 below without the second opening region S2, and may have a shape recessed inwardly from the second connection region CA2 toward the substrate 101.

Specifically, in the second connection region CA2, the first capacitor electrode layer 231 may extend to flatly cover the intermetallic insulating layer 189 without the second opening region S2, and the first dielectric layer 221 may be disposed thereon. On the second opening region S2 of the second capacitor electrode layer 232, the second dielectric layer 222 may be disposed on the first dielectric layer 221, the third capacitor electrode layer 233 may be inwardly recessed thereon, and the third dielectric layer 223 may be conformally disposed thereon. When the second opening region S2 of the fourth capacitor electrode layer 234 overlaps and exposes the third dielectric layer 223 in the lower portion, the fourth dielectric layer 224 may extend from an upper surface of the fourth capacitor electrode layer 234 along a side surface of the second opening region S2 to an upper surface of the third dielectric layer 223 thereon. The fifth capacitor electrode layer 235 may be recessed inwardly thereon.

As described above, the fourth dielectric layer 224 may include an inwardly recessed outermost surface Sa in the first connection region CA1, and the fifth capacitor electrode layer 235 may include an inwardly recessed outermost surface Sb in the second connection region CA2.

In the spacing region in which the capacitor electrode layer 230 is not disposed, the first to fourth dielectric layers 221-224 may be in contact with each other on the first insulating layer 211 and may be consecutively disposed.

A second insulating layer 225 may be formed while covering the capacitor electrode layer 230. The second insulating layer 225 may include a material different from the first to fourth dielectric layer 221-224, and may include, for example, one from among silicon oxide, silicon nitride, silicon oxynitride, and silicon oxycarbide. The second insulating layer 225 may evenly cover an upper surface of the capacitor electrode layer 230.

The first via structure V1 and the second via structure V2 may be disposed in the capacitor electrode layer 230 to penetrate the first opening region S1 and the second opening region S2, respectively.

The first via structure V1 may connect the lower interconnection structure 210 disposed below the capacitor electrode layer 230 to the upper interconnection structure 240 disposed above the capacitor electrode layer 230.

The lower interconnection structure 210 may be disposed on the intermetallic insulating layer 189 and may be configured as interconnections connected to the upper interconnections (e.g., the interconnection region 180) therebelow through a plurality of plugs. As an example, in the pixel circuit of the pixel PX in FIG. 2, the lower interconnection structure 210 may be connected to the third floating diffusion region FD3 connected to the second transfer transistor TX2 and the switch element SW, but an example embodiment thereof is not limited thereto.

The lower interconnection structure 210 may be patterned in a position connected to the upper interconnections (e.g., the interconnection region 180), and may include a first sub-lower pattern overlapping with the first via structure V1 in the Z-direction, a second sub-lower pattern overlapping with the second via structure V2 in the Z-direction and a third sub-lower pattern overlapping with the third via structure V3 in the Z-direction. The lower interconnection structure 210 may include a conductive material, for example, metal such as tungsten, copper, aluminum, titanium and tantalum. The lower interconnection structure 210 may have a second thickness t2 greater than the first thickness t1. For example, the second thickness t2 may be 1.5 to 3 times the first thickness t1. The first insulating layer 211 may be disposed such as to cover the lower interconnection structure 210.

The upper interconnection structure 240 may be patterned in a position connected to the via structures (e.g., the first via structure V1 and the second via structure V2) in a lower portion on the second insulating layer 225, and may include a first sub-upper pattern overlapping with the first via structure V1 in the Z-direction, a second sub-upper pattern overlapping with the second via structure V2 in the Z-direction, and a third sub-upper pattern overlapping with the third via structure V3 in the Z-direction. The upper interconnection structure 240 may include a conductive material such as, for example, metal such as tungsten, copper, aluminum, titanium, and tantalum. The upper interconnection structure 240 may have a third thickness t3 larger than the first thickness t1, the second thickness t2 and the third thickness t3 may be the same, and the third thickness t3 may be 1.5 to 3 times the first thickness t1.

The first via structure V1, the second via structure V2, and the third via structure V3 may be disposed between the lower interconnection structure 210 and the upper interconnection structure 240.

As illustrated in FIG. 4B, when viewed on a plane, the first via structure V1 and the second via structure V2 may be disposed in the storage capacitors SC, and the third via structure V3 may be disposed in a spacing between the storage capacitors SC.

The first via structure V1, the second via structure V2, and the third via structure V3 may be disposed on the XY plane to be aligned in the direction D1, which is the slope direction having a slope with the X-direction and the Y-direction. Specifically, when the third via structure V3 is disposed in a central region of the spacing between the four storage capacitors SC disposed in a 2×2 format, the conceptual lines connecting the third via structures V3 to each other, disposed in the neighboring spacing on a diagonal 11, may overlap the diagonal 11 of the storage capacitors SC and may be defined as an extension line of the diagonal 11 of the storage capacitors SC. The first via structure V1, the second via structure V2 and the third via structure V3 may be disposed linearly on the extension line of the diagonal 11 of the storage capacitor SC. Specifically, the first via structure V1 and the second via structure V2 may be disposed in the storage capacitor structures SC, and the third via structure V3 may be disposed as an external via structure in the spacing between the storage capacitor structures SC.

In this case, the first via structure V1 and the second via structure V2 may penetrate the capacitor electrode layers 230 of the storage capacitors SC, and may be spaced apart from each other in the area formed by the storage capacitors SC to satisfy a first spacing distance of da or more. For example, when the first via structure V1 is disposed close to one corner, the second via structure V2 may be disposed close to another corner at the diagonal 11 of the capacitor electrode layer 230. Accordingly, the first connection region CA1 in which the first via structure V1 is disposed, and the second connection region CA2 in which the second via structure V2 is disposed may also be spaced apart from each other to satisfy a predetermined spacing distance or more. As the first via structure V1 and the second via structure V2 are spaced apart from each other by a maximum distance therebetween in one capacitor structure SC, a leakage path may be reduced.

On the extension line of the diagonal 11 of the storage capacitor SC, when the first via structure V1 and the second via structure V2 are spaced apart from each other to have a first spacing distance da or more therebetween, the third via structure V3 adjacent to the first via structure V1 may have a second spacing distance db from the first via structure V1, and the third via structure V3 adjacent to the second via structure V2 may have a third spacing distance dc from the second via structure V2. The second spacing distance db and the third spacing distance dc may be the same, but an example embodiment thereof is not limited thereto. The second spacing distance db and the third spacing distance dc may be smaller than the first spacing distance da.

As described above, the first via structure V1, the second via structure V2 and the third via structure V3 are disposed linearly on the extension line of diagonal 11 of the storage capacitor SC, and may ensure the maximum spacing distance, and the third via structure V3 disposed in the spacing between the storage capacitors SC may ensure the spacing distance by chamfering of the capacitor electrode layers 230 of the storage capacitor structures SC, thereby preventing short circuits.

The first via structure V1 may penetrate the capacitor electrode layer 230 to connect the first sub-patterns of the lower interconnection structure 210 to the upper interconnection structure 240.

The first via structure V1 may extend in the Z-direction, may penetrate the first opening region S1 of the first capacitor electrode layer 231, the third capacitor electrode layer 233 and the fifth capacitor electrode layer 235, that is, odd-numbered electrode layers, in the first connection region CA1, and may be physically and electrically spaced apart from the odd-numbered electrode layers (e.g., the first capacitor electrode layer 231, the third capacitor electrode layer 233, and the fifth capacitor electrode layer 235). The first via structure V1 may also penetrate the second capacitor electrode layer 232 and the fourth capacitor electrode layer 234, that is, even-numbered electrode layers (e.g., the second capacitor electrode layer 232 and the fourth capacitor electrode layer 234), and may be physically in direct contact with and electrically connected to the even-numbered electrode layers (e.g., the second capacitor electrode layer 232 and the fourth capacitor electrode layer 234). Specifically, the side surface of the even-numbered electrode layers (e.g., the second capacitor electrode layer 232 and the fourth capacitor electrode layer 234) and the side surface of the via structure V1 may be in direct contact with each other and may form electrical connections.

A lower end width W2 of the first via structure V1 may have a side surface inclined to be smaller than an upper end width W1 thereof, and the width of the first via structure V1 may increase in a direction away from the substrate 101 in the Z-direction. The upper end width W1 of the via structure V1 may be smaller than a width W3 of the first opening region S1 of the odd-numbered electrode layers (e.g., the first capacitor electrode layer 231, the third capacitor electrode layer 233, and the fifth capacitor electrode layer 235), and accordingly, in the first opening region S1, the side surfaces of the odd-numbered electrode layers (e.g., the first capacitor electrode layer 231, the third capacitor electrode layer 233, and the fifth capacitor electrode layer 235) and the side surfaces of the first via structure V1 may not be in contact with each other. The cross-sectional shape of the via structure V1 may be a quadrangular shape, but an example embodiment thereof is not limited thereto, and the shape may include various shapes such as a circular, oval, and polygonal shape. In this case, the shape of the first opening region S1 of the capacitor electrode layers 230 may change depending on the cross-sectional shape of the via structure V1. As illustrated in FIG. 6A, the shape of the cross-sectional surface of the first via structure V1 and the first opening region S1 may have similar concentric shapes to be spaced apart from each other so as to satisfy the first distance d1 from the side surface of the first via structure V1 to the side surface of the first opening region S1. The first via structure V1 may also include a conductive material such as, for example, metal such as tungsten, copper, aluminum, titanium and tantalum.

The second via structure V2 may extend in the Z-direction, may penetrate the second opening region S2 of the second dielectric layer 222 and the fourth dielectric layer 224, that is, even-numbered dielectric layers (e.g., the second dielectric layer 222 and the fourth dielectric layer 224), and may be physically and electrically spaced apart from the even-numbered dielectric layers (e.g., the second dielectric layer 222 and the fourth dielectric layer 224). Also, the second via structure V2 may penetrate the first capacitor electrode layer 231, the third capacitor electrode layer 233 and the fifth capacitor electrode layer 235, that is, odd-numbered electrode layers (e.g., the first capacitor electrode layer 231, the third capacitor electrode layer 233, and the fifth capacitor electrode layer 235), and may be in physically direct contact with and electrically connected to the odd-numbered electrode layers (e.g., the first capacitor electrode layer 231, the third capacitor electrode layer 233, and the fifth capacitor electrode layer 235). Specifically, the side surface of odd-numbered electrode layers (e.g., the first capacitor electrode layer 231, the third capacitor electrode layer 233, and the fifth capacitor electrode layer 235) and the side surface of the second via structure V2 may be in direct contact with each other and may form electrical connections.

A lower end width W5 of the second via structure V2 may have an inclined side surface such that the lower end width W5 of the second via structure V2 may be smaller than an upper end width W4 thereof, and the width of the second via structure V2 may increase in a direction away from the substrate 101 in the Z-direction. The upper end width W4 of the second via structure V2 may be smaller than a width W6 of the second opening region S2 of the odd-numbered electrode layers (e.g., the first capacitor electrode layer 231, the third capacitor electrode layer 233, and the fifth capacitor electrode layer 235), and accordingly, in the second connection region CA2, the side surfaces of the odd-numbered electrode layers (e.g., the first capacitor electrode layer 231, the third capacitor electrode layer 233, and the fifth capacitor electrode layer 235) and the side surfaces of the second via structure V2 may not be in contact with each other.

As illustrated in FIG. 6B, the shape of the cross-sectional surface of the via structure V2 and the second opening region S2 may have similar concentric shapes such that a second distance d2 from the side surface of the second via structure V2 to the side surface of the second opening region S2 may be satisfied. The shape of the cross-sectional surface of the second via structure V2 may be the same as the shape of the cross-sectional surface of the first via structure V1, and the sizes thereof may also be substantially the same, but an example embodiment thereof is not limited thereto. The second via structure V2 may also include a conductive material such as, for example, metal such as tungsten, copper, aluminum, titanium and tantalum.

The third via structure V3 may be disposed in a spacing between the capacitor electrode layers 230. To have a sufficient spacing distance between the third via structure V3 and the capacitor electrode layers 230, corners of the capacitor electrode layer 230 may be cut and chamfered. In other words, the distance between the third via structure V3 and the capacitor electrode layer 230 may be further extended by chamfering the angular edge portion to have a surface. The corners of the capacitor electrode layer 230 may be cut to have a curved surface or may be cut diagonally, but an example embodiment thereof is not limited thereto. The third via structure V3 may extend in the Z-direction to connect the third sub-patterns of the lower interconnection structure 210 and the upper interconnection structure 240, and may penetrate the first insulating layer 211, the first to fourth dielectric layer 221-224 and the second insulating layer 225. The third via structure V3 may have an inclined side surface such that a lower end width W8 may be smaller than an upper end width W7 thereof, and the width of the third via structure V3 may increase in a direction away from the substrate 101 in the Z-direction. The upper end width W7 of the third via structure V3 may be smaller than the upper end width W1 of the first via structure V1 and the upper end width W4 of the second via structure V2, and the lower end width W8 may also be smaller than the lower end width W2 of the first via structure V1 and the lower end width W5 of the second via structure V2. In other words, the size of the third via structure V3 may be smaller than the sizes of the first via structure V1 and the second via structure V2. The third via structure V3 may function as a portion of the ground region GND (e.g., a ground interconnection) to provide a ground voltage of the pixel circuits (e.g., the pixels PX) in the lower portion, rather than as a connection structure to provide the voltage of both ends of the storage capacitor SC, and may also be a portion of the interconnection to discharge an output voltage of the lower portion of the pixel circuits (e.g., the pixels PX).

The third via structure V3 may not penetrate the capacitor electrode layer 230, and may continuously penetrate the insulating layers (e.g., the first insulating layer 211 and the second insulating layer 225), or the capacitor dielectric layer 220, such that high energy etching may not be necessary, and accordingly, a via may be formed without a via hole having a large area. Similarly to the first via structure V1 and the second via structure V2, the third via structure V3 may include metal such as tungsten, copper, aluminum, titanium, and tantalum.

As described above, the first via structure V1 and the second via structure V2, penetrating through the storage capacitor SC may be selectively connected to the odd-numbered electrode layer or the even-numbered electrode layer on the side surface, such that the plurality of capacitors stacked in a plurality of layers may be connected each other in parallel. Accordingly, capacitance in the storage capacitor SC may increase in proportion to the area of the capacitor electrode layers 230 connected to each other by the via structures (e.g., the first via structure V1 and the second via structure V2). That is, four capacitors may be connected to each other in parallel in the first to fifth capacitor electrode layers 231-235 and the first to fourth dielectric layer (e.g., the capacitor dielectric layers 220) therebetween, and the sum of the capacitance of the four capacitors may be the total capacitance of the storage capacitor SC.

As described above, the capacitor electrode layers 230 of the storage capacitor SC may be formed in a horizontal plate-type stack structure on the substrate 101, the respective capacitor dielectric layers 220 may be disposed therebetween, and the via structures (e.g., the first via structure V1 and the second via structure V2) may be formed to connect the layers to each other in parallel, thereby forming a storage capacitor SC having large capacitance in a relatively small area.

The storage capacitor SC may be disposed in each pixel PX, thereby providing an element having sufficient capacitance and improved reliability.

In FIGS. 3 to 6C, a single storage capacitor SC may be included in the pixel PX, but an example embodiment thereof is not limited thereto, and when a plurality of the storage capacitor SC are included in the pixel PX, the storage capacitors SC may be a plurality of stacked type capacitors that are disposed by dividing the area corresponding to each pixel PX. Also, the first via structure V1 and the second via structure V2 connecting the components to each other in parallel may penetrate through the respective stacked-type capacitors.

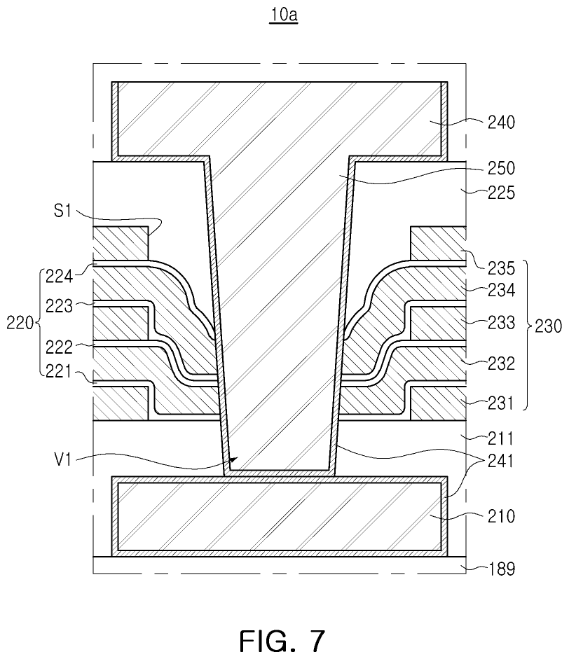

In the description below, an example embodiment will be described with reference to FIGS. 7 to 11. FIGS. 7 to 9 are enlarged diagrams illustrating pixels of an image sensor according to an example embodiment, illustrating a region B.

Referring to FIG. 7, a pixel array 10a in an example embodiment may be configured the same as the pixel array 10 in FIG. 6A, except that the first to third via structures V1-V3, the lower interconnection structure 210, and the upper interconnection structure 240 include the diffusion barrier 241.

Specifically, when the lower interconnection structure 210, the upper interconnection structure 240 and the first to third via structures V1-V3 include conductive material layers 250 such as tungsten, copper, aluminum, titanium and tantalum, to prevent the conductive material layer 250 from diffusing into the first insulating layer 211 and the second insulating layer 225, a diffusion barrier 241 may be included on the surface thereof.

The diffusion barrier 241 may be disposed on a side surface and an upper surface of the lower interconnection structure 210, and the diffusion barrier 241 may be disposed on side surfaces and bottom surfaces of the first to third via structures V1-V3 thereon. Also, the diffusion barrier 241 may be disposed on a lower surface and a side surface of the upper interconnection structure 240, and when an additional insulating layer is disposed on an upper portion of the upper interconnection structure 240, the diffusion barrier 241 may also be disposed on the upper surface of the upper interconnection structure 240.

When the first to third via structures V1-V3 and the upper interconnection structure 240 are formed simultaneously through the same process (e.g., a damascene process), the diffusion barrier 241 may be disposed consecutively, and the first to third via structures V1-V3 connected to the upper interconnection structure 240 may be formed as an integrated structure without a boundary therebetween. That is, the diffusion barrier 241 may be disposed between the lower interconnection structure 210 and the first to third via structures V1-V3, but the diffusion barrier 241 may not be disposed between the first to third via structures V1-V3 and the upper interconnection structure 240. However, when the first to third via structures V1-V3 and the upper interconnection structure 240 are formed in different processes, the diffusion barrier 241 may be disposed between the first to third via structures V1-V3 and the upper interconnection structure 240. The diffusion barrier 241 may be metal nitride such as titanium nitride (TiN) or tantalum nitride (TaN), but an example embodiment thereof is not limited thereto.

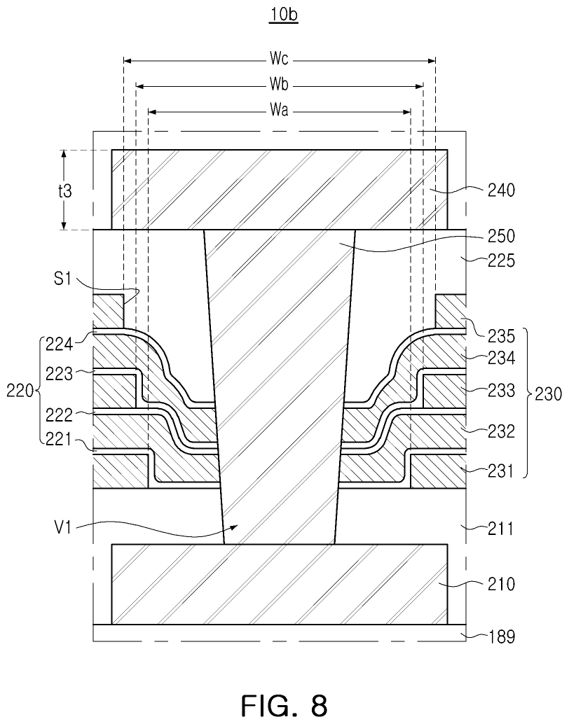

Referring to FIG. 8, a pixel array 10b in an example embodiment may be configured the same as the pixel array 10 in FIG. 6A, except that widths of the opening regions (e.g., the first opening region S1 and the second opening region S2) of the capacitor electrode layers 230 are different.

Specifically, the first opening region S1 of each of the first capacitor electrode layer 231, the third capacitor electrode layer 233, and the fifth capacitor electrode layer 235 in the first connection region CA1 penetrated by the first via structure V1 may have different widths Wa, Wb, and Wc.

The first opening region S1 may have a greater width Wa, Wb, and Wc in a direction away from the substrate 101, the first capacitor electrode layer 231 of the lower portion may include the first opening region S1 having the smallest width Wa, and the fifth capacitor electrode layer 235 of the uppermost portion may include the first opening region S1 having the largest width Wc.

The configuration described above may also be applied to the second opening region S2 of the second dielectric layer 222 and the fourth dielectric layer 224 in the second connection region CA2 penetrated by the second via structure V2. Accordingly, the spacing distances (e.g., the first distance d1 and the second distance d2) in the first via structure V1 and the second via structure V2 each having a width increasing upwardly, and the opening regions (e.g., the first opening region S1 and the second opening region S2) of each electrode layer 230 may be maintained to be uniform. Accordingly, as the widths of via structures (e.g., the first via structure V1 and the second via structure V2) increase in an upper portion, the risk of short with the capacitor electrode layer 230 disposed in an upper portion may be significantly reduced.

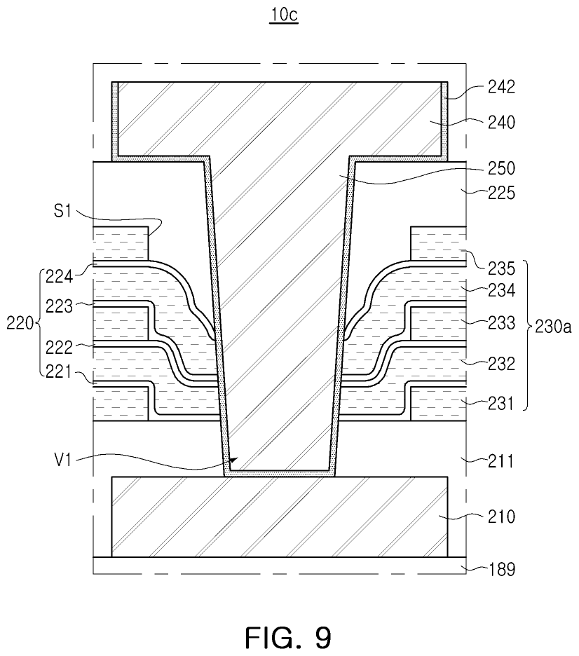

Referring to FIG. 9, the example embodiment may be configured the same as the image sensor in FIG. 6A, except that the first to fifth capacitor electrode layers 231-235 of the capacitor electrode layer 230a may include polysilicon

Specifically, the stack structure of the first to fifth capacitor electrode layers 231-235 forming the capacitor electrode layer 230a may include silicon doped with impurities, specifically polysilicon doped with impurities. In this case, when the lower interconnection structure 210, the upper interconnection structure 240 and the via structures (e.g., the first via structure V1 and the second via structure V2) include a conductive material such as tungsten, copper, aluminum, titanium and tantalum, ohmic contact may be induced to enable electrical connection by allowing the side surface of the via structures (e.g., the first via structure V1 and the second via structure V2) to be in contact with the capacitor electrode layer 230a. To this end, the side surfaces of via structures (e.g., the first via structure V1 and the second via structure V2) may further include an ohmic contact layer 242.

The ohmic contact layer 242 may be disposed on the side surface of the via structure, and when the via structures (e.g., the first via structure V1 and the second via structure V2) and the upper interconnection structure 240 are formed simultaneously, the ohmic contact layer 242 may extend to the lower surface and the side surface of the upper interconnection structure 240, but an example embodiment thereof is not limited thereto. The ohmic contact layer 242 may be metal nitride such as titanium nitride (TiN) or tantalum nitride (TaN), but an example embodiment thereof is not limited thereto.

As described above, when the substrate 101 and the capacitor electrode layer 230a (e.g., horizontal plate-type capacitor electrode layers) are stacked, the capacitor electrode layer 230a may include a poly-silicon material, and accordingly, a polysilicon-dielectric layer-polysilicon capacitor (PIP capacitor) may be formed.

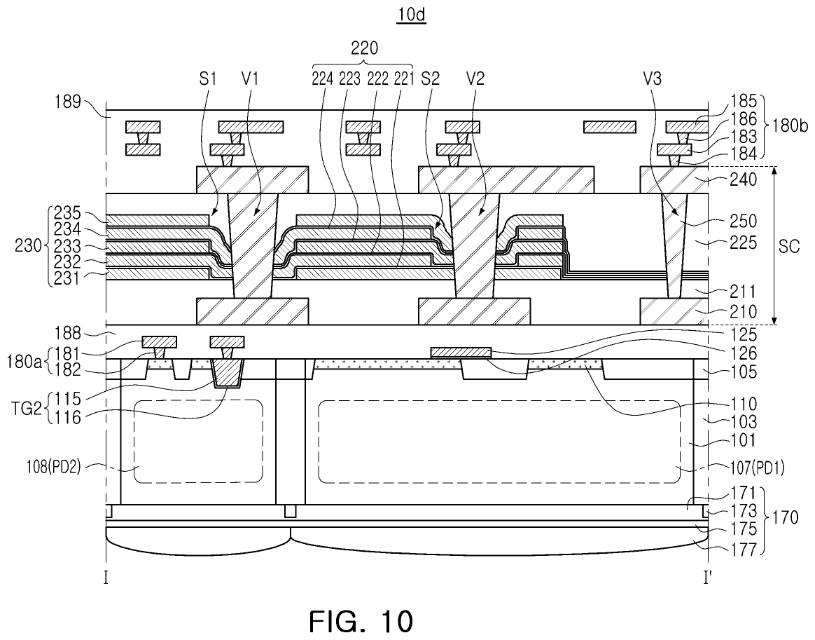

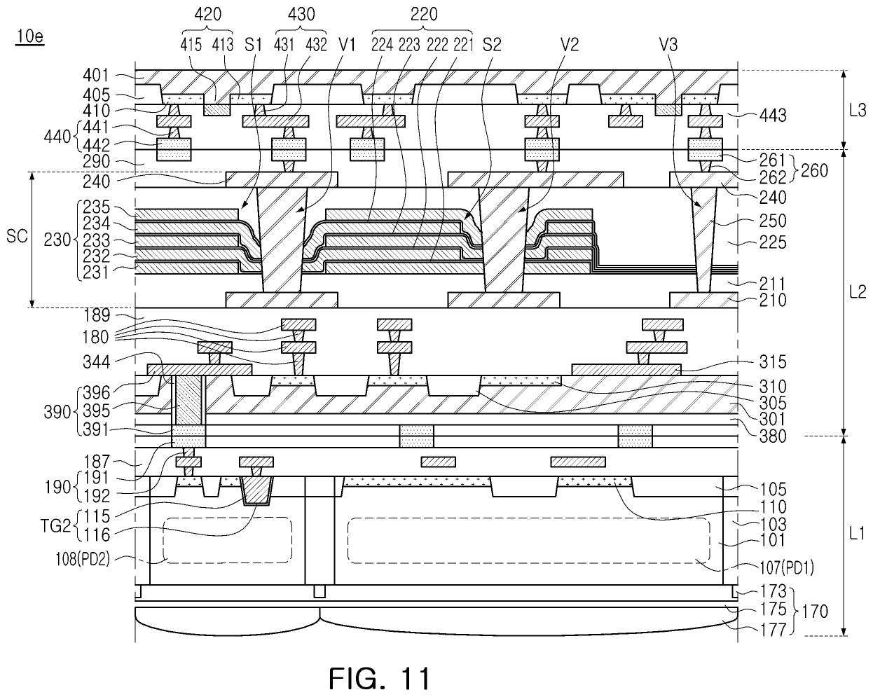

FIGS. 10 and 11 are cross-sectional diagrams illustrating a cross-section of an image sensor according to an example embodiment.

Referring to FIG. 10, the example embodiment may be configured the same as in FIG. 5, except that a portion of the interconnection region 180 above a pixel array of the image sensor 10d may be disposed in an upper portion of the storage capacitor SC.

Specifically, the interconnection region 180 may include a plurality of elements on the substrate 101 such as for example, a first circuit interconnection region 180a including the first circuit interconnections 181 and first plugs 182, and connecting gate structures (e.g., the gate structure 125, the gate structure 126, the gate electrode 115, and the transfer gate insulating layer 116) of transistors to floating diffusion regions (e.g., the first floating diffusion region FD1, the second floating diffusion region FD2, and the third floating diffusion region FD3). The first circuit interconnection region 180a may be applied as a portion of a pattern for connecting a plurality of elements or for connecting to the interconnections (e.g., the second circuit interconnections 183 and the third circuit interconnections 185) on the other levels.

A first upper insulating layer 188 may be disposed between the storage capacitor SC while covering the first circuit interconnections 181.

The storage capacitor SC may be disposed on the first upper insulating layer 188, and the storage capacitor SC may be the same as previously described.

A second circuit interconnection region 180b may be disposed on the upper interconnection structure 240 of the storage capacitor SC. The first circuit interconnection region 180a may include second plugs 184, second circuit interconnections 183 connected to the second plugs 184, third plugs 186 on the second circuit interconnections 183, and third circuit interconnections 185 connected to the third plugs 186.

A second upper insulating layer (e.g., the intermetallic insulating layer 189) may be disposed on the second plugs 184, the third plugs 186, and the circuit interconnections (e.g., the second circuit interconnections 183 and the third circuit interconnections 185).

As described above, when a portion of the circuit interconnection regions (e.g., the interconnection regions 180) is disposed as an upper portion of the storage capacitor SC, the lower interconnection structure 210 and the upper interconnection structure 240 of the storage capacitor SC may also be connected to the circuit interconnection regions (e.g., the interconnection regions 180) through plugs. In this case, the third via structure V3 may function as a ground voltage, and also as a connection structure connecting the first circuit interconnections 181 in a lower portion to the second circuit interconnections 183 in an upper portion.

Referring to FIG. 11, an image sensor 10e may include a third chip structure L3 forming a logic circuit 20, a second chip structure L2 disposed on the third chip structure L3 and including a pixel array 10, and a first chip structure 11 thereon.

The image sensor 10e may include a first chip structure L1 including a first substrate (e.g., the substrate 101), a second chip structure L2 including a second substrate 301, and a third chip structure L3 including a third substrate 401. The third chip structure L3 may be configured as a logic chip including the logic circuit 20, and the first chip structure L1 and the second chip structure L2 may be configured as image sensor chips including a plurality of pixels PX. The first chip structure L1 may include a transfer transistor, and the second chip structure L2 may include transistors other than the transfer transistor.

The first chip structure 11 may include transfer transistors (e.g., the first transfer transistor TX1 and the second transfer transistor TX2), floating diffusion regions (e.g., the first floating diffusion region FD1, the second floating diffusion region FD2, and the third floating diffusion region FD3) and photodiodes (e.g., the first photodiode 107 and the second photodiode 108) of the structure of the substrate 101 illustrated in FIGS. 1 to 6C, and an upper portion of the transfer transistors (e.g., the first transfer transistor TX1 and the second transfer transistor TX2) may include a first bonding structure 190. The first chip structure 11 may include the optical unit 170 in a lower portion thereof, and the description thereof may be the same as the description provided with reference to FIG. 5.

The second chip structure L2 may include the second substrate 301 which may have a lower surface opposing the first chip structure 11 and an upper surface opposing the lower surface, an element separator 305 defining an active region 110 in the second substrate 301, second circuit elements 315 on the upper surface of the second substrate 301, an interconnection region 180 connected to the second circuit elements 315, a storage capacitor SC, a second lower bonding structure 390 on the lower surface of the second substrate 301, a second upper bonding structure 260 on the upper surface of the second substrate 301, a second lower insulating layer 380 on the lower surface of the second substrate 301, and a second upper insulating layer 290 on the upper surface of the second substrate 301.

The second circuit elements 315 may be transistors other than transfer transistors (e.g., the first transfer transistor TX1 and the second transfer transistor TX2). The interconnection region 180 may be disposed between the second substrate 301 and the third chip structure L3. The interconnection region 180 may apply an electrical signal to the second circuit elements 315. The second upper bonding structure 260 may be connected to a portion of the storage capacitor SC or may be connected to an interconnection structure thereon. The second upper bonding structure 260 may be provided for bonding with the third chip structure L3. The second upper bonding structure 260 may include a metal material such as copper (Cu). The second upper bonding structure 260 may include a second bonding pad 261 and a second bonding via 262 connected to the second bonding pad 261. The second bonding pad 261 of the second chip structure L2 may be in contact with the third bonding pad 442 of the third chip structure L3. The second bonding pad 261 may function as a bonding layer and may also provide an electrical connection path with the third chip structure L3.

The second lower insulating layer 380 may include a bonding insulating layer having a predetermined thickness from the lower surface. The bonding insulating layer may be provided for dielectric-dielectric bonding with the bonding insulating layer of the first chip structure L1.

The second lower bonding structure 390 may be provided for bonding with the first chip structure L1. The second lower bonding structure 390 may include a third bonding pad 391 disposed on the lower surface of the second substrate 201, a landing structure 396 disposed on the upper surface of the second substrate 301, and a third bonding via 395 disposed between the third bonding pad 391 and the landing structure 396. The third bonding pad 391 may include a metal material such as copper (Cu), and the third bonding via 395 may include a metal material such as copper (Cu) and tungsten (W). The third bonding pad 391 may include the same metal material as a material of the third bonding via 395, but an example embodiment thereof is not limited thereto.

The third chip structure L3 may include the third substrate 401, a third interconnection structure 430 connected to third circuit elements 420, a third bonding structure 440 on the third interconnection structure 430, and a logic insulating layer 443 covering the third circuit elements 420 and the third interconnection structure 430 on the third substrate 401. The third bonding structure 440 may be connected to the third interconnection structure 430 on the third interconnection structure 430. The third bonding structure 440 may include a metal material such as copper (Cu). The third bonding structure 440 may include a third bonding pad 442 and a third bonding via 441 connected to the third bonding pad 442. The third bonding pad 442 of the third chip structure L3 may function as a bonding layer with the second chip structure L2 and may provide an electrical connection path with the second chip structure L2. The logic insulating layer 443 may cover a portion of the third bonding structure 440 while covering the third circuit elements 420 and the third interconnection structure 430.

As described above, by isolating the image sensor chip including the pixel array into two chip structures (e.g., the first chip structure L1 and the second chip structure L2), and performing hybrid bonding between the chip structures (e.g., the first chip structure L1 and the second chip structure L2) by the bonding structure (e.g., the first bonding structure 190 and the second lower bonding structure 390) to electrically connecting the structures to each other, the image sensor 1e by hybrid bonding between three chip structures (e.g., the first chip structure L1 the second chip structure L2, and the third chip structure L3) may be implemented.

In the above description, the image sensor 1 in which the pixel circuit of the pixel PX may be divided into the first pixel region PA1 and the second pixel region PA2, and a single storage capacitor SC may be included is described. However, alternatively, a pixel circuit of the pixel PX may be partitioned as a pixel region PA, and each pixel circuit of the pixel PX may include a storage capacitor SC, and the corresponding storage capacitor SC may be disposed on the pixel region PA corresponding to the pixel circuit of the pixel PX.

As an example, the storage capacitor SC of the example embodiment may be applied to various pixel circuits including the storage capacitor SC to implement global shuttering.

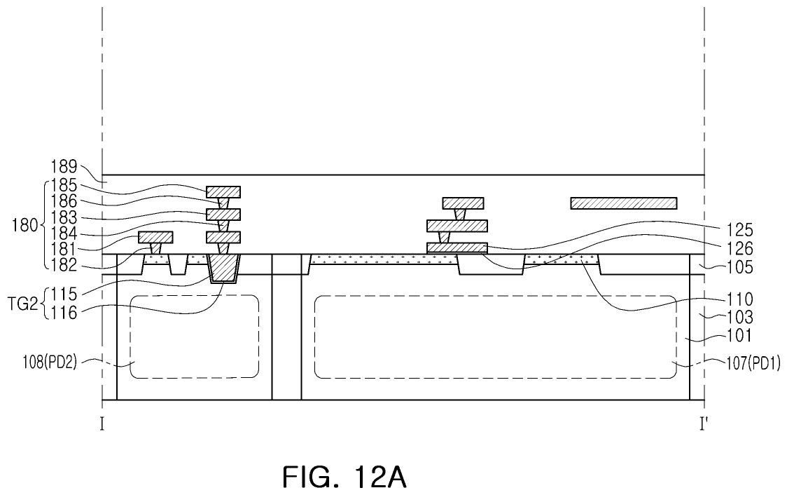

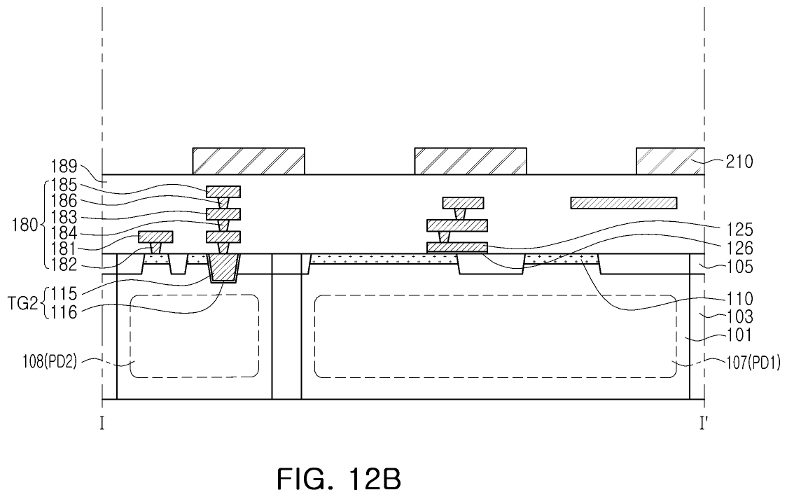

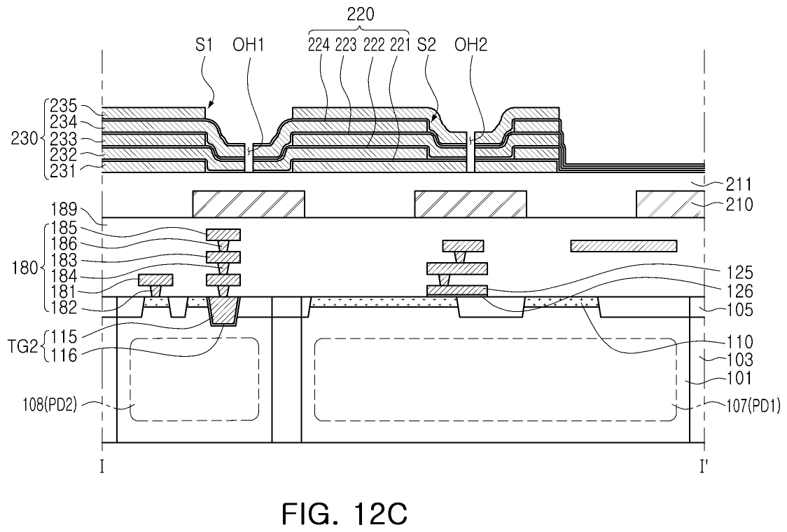

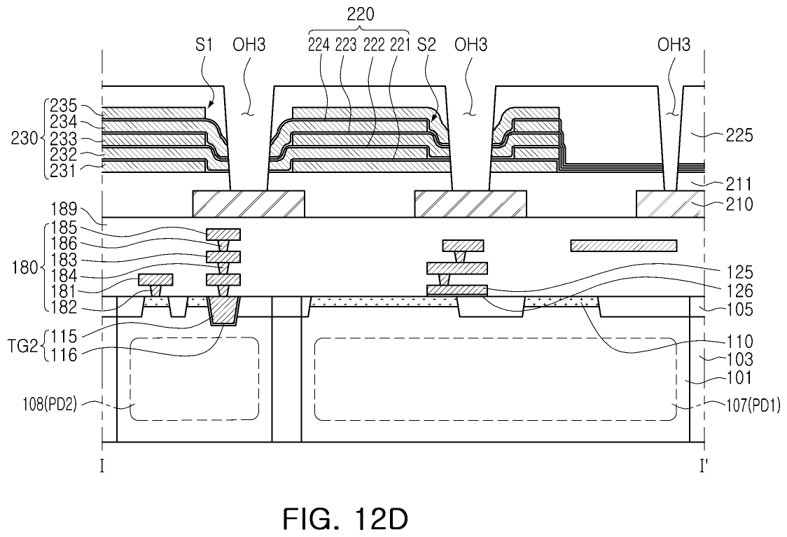

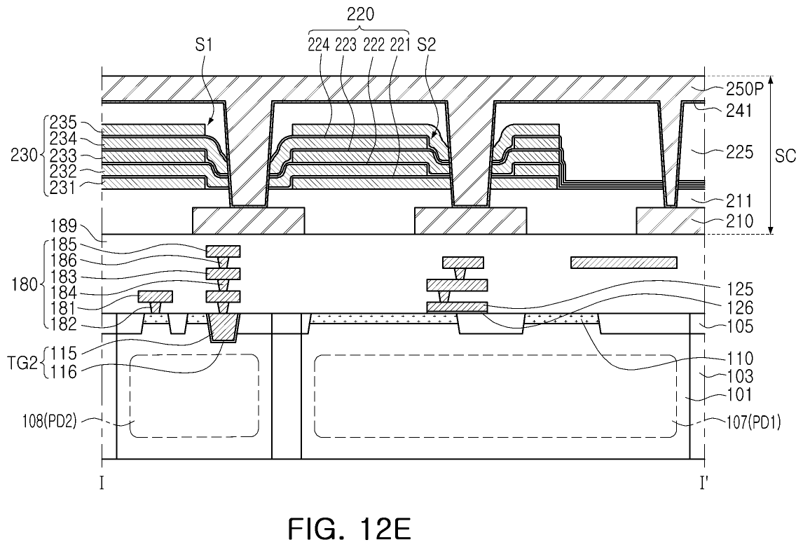

Hereinafter, a method of manufacturing an image sensor in an example embodiment will be described with reference to FIGS. 12A to 12E.

FIGS. 12A to 12E are cross-sectional diagrams illustrating a method of manufacturing an image sensor illustrated in FIG. 5.

Referring to FIG. 12A, a substrate 101 may be prepared, a pixel separator 103 may be formed in the substrate 101, photodiodes (e.g., a first photodiode 107 and a second photodiode 108) may be formed in the pixel regions (e.g., the first pixel region PA1 and the second pixel region PA2), respectively, an element separator 105 defining the active region 110 may be formed on the surface, and circuit elements (e.g., gate structures 125), an interconnection structure (e.g., the interconnection region 180), and an intermetallic insulating layer 189 covering the components on the substrate 101 may be formed.

In the substrate 101, the photodiodes (e.g., the first photodiode 107 and the second photodiode 108) may be formed by photoelectric conversion regions (e.g., the first photodiode PD1 and the second photodiode PD2), an element separator 105 defining the active region 110 of the substrate 101 may be formed, an insulating liner may be formed on the substrate 101, a semiconductor material layer may be deposited and a patterning process may be performed, thereby forming the circuit elements (e.g., the gate structures 125). The transfer gate structures (e.g., the first transfer gate structure TG1, the second transfer gate structure TG2) and other transistor gate electrodes (e.g., the gate structure 125) may have different patterns depending on the shape thereof. The transfer gate structures (e.g., the first transfer gate structure TG1 and the second transfer gate structure TG2) may extend to a region below the surface of the substrate 101 to have a longer depth to reach the region adjacent to the photodiodes (e.g., the first photodiode 107 and the second photodiode 108) in the substrate 101. An insulating liner covering each gate electrode (e.g., the gate structure 125) and the exposed upper surface of the substrate 101 may be formed, an interconnection region 180 (e.g., an interconnection structure) may be formed consecutively, and an intermetallic insulating layer 189 may be formed. By performing a planarization process, the upper surface of the intermetallic insulating layer 189 may be formed to have a flat shape.

Referring to FIG. 12B, the lower interconnection structure 210 may be formed on the intermetallic insulating layer 189. While the lower interconnection structure 210 is formed, in the case in which the lower interconnection structure 210 is simultaneously formed with a plug of an uppermost end of the interconnection region 180 (e.g., an interconnection structure), the lower interconnection structure 210 may be formed using a damascene process. The lower interconnection structure 210 may be formed to have a second thickness t2 by over-plating through electroplating of copper, tungsten, aluminum and performing patterning. The lower interconnection structure 210 may be formed to include a first lower pattern and a second lower pattern overlapping with the first connection region CA1 and the second connection region CA2 in the storage capacitor SC in the Z-direction, and to include a third lower pattern other than the storage capacitor SC.

Referring to FIG. 12C, a first insulating layer 211 may be formed while covering the lower interconnection structure 210, and capacitor electrode layers 230 (e.g., capacitor metal layers) may be formed.

The first insulating layer 211 may be formed to have a relatively great thickness to not expose the lower interconnection structure 210, and a planarization process may be performed to planarize the upper surface.

The capacitor electrode layers 230 may be stacked on the first insulating layer 211.

To form the storage capacitor SC, the first to fifth capacitor electrode layers 231-235 (e.g., metal layers) and the first to fourth dielectric layers 221-224 may be alternately stacked. First, the first to fifth capacitor electrode layers 231-235 may be formed to have a first thickness t1 through chemical physical vapor deposition (CVD) of a conductive material. In this case, each of the capacitor electrode layers (e.g., the first to fifth capacitor electrode layer 231-235) may be deposited, and may be patterned to have the shape in FIG. 4B. In this case, a corner of each of the first to fifth capacitor electrode layers 231-235 may be chamfered to have a curved surface or a diagonal line.

When each of the first to fifth capacitor electrode layers 231-235 are patterned, the first opening region S1 may be formed on odd-numbered electrode layers (e.g., the first capacitor electrode layer 131, the third capacitor electrode layer 133, and the fifth capacitor electrode layer 135) in the first connection region CA1 in which the first via structure V1 is disposed, and the second opening region S2 may be formed on even-numbered electrode layers (e.g., the second electrode layer 132 and the fourth electrode layer 134) in the second connection region CA2 in which the second via structure V2 is disposed. In this case, another electrode layer in which the first opening region S1 and the second opening region S2 are not formed may have a region recessed inwardly toward the substrate 101 by the first opening region S1 and the second opening region S2 in a lower portion. The first opening OH1 may be further formed in a central region of the inwardly recessed region in the first connection region CA1. The first opening OH1 may later function as a marker for laser alignment when a via hole is formed. The first opening OH1 may be formed to have a width much narrower than the widths of the opening regions (e.g., the first opening region S1 and the second opening region S2), and may not be provided.

In the second connection region CA2 in which the second via structure V2 is disposed, the second opening OH2 may be formed similar to the first opening OH1, and the second opening OH2 may penetrate the first capacitor electrode layer 231, the third capacitor electrode layer 233, and the fifth capacitor electrode layer 235.

The capacitor electrode layers 230 may be removed from the region in which the third via structure V3 is disposed, such that the first to fourth dielectric layers 221-224 may be conformally deposited on the first insulating layer 211.

The first to fourth dielectric layers 221-224 may be formed to alternate with each electrode layer 230 and may conformally cover each of electrode layers 230. In this case, the first to fourth dielectric layers 221-224 may be conformally deposited along the first opening region S1 and the second opening region S2, such that a portion of the first to fourth dielectric layers 221-224 may be in direction contact with each other in the first opening region S1 and the second opening region S2. The first opening OH1 and the second opening OH2 may be formed together while penetrating the first to fourth dielectric layers 221-224, but differently, the first opening OH1 and the second opening OH2 may be formed limitedly in the capacitor electrode layer 230.

As illustrated in FIG. 12D, a second insulating layer 225 may be formed while covering the entirety of the capacitor electrode layer 230 of the storage capacitor SC. Via holes OH3 for opening the lower interconnection structure 210 of the lower portion may be formed from an upper surface of the second insulating layer 225.

The via holes OH3 may be formed in the region corresponding to the first via structure V1, the region corresponding to the second via structure V2, and the region corresponding to the third via structure V3, respectively, and the via holes OH3 corresponding to the first via structure V1 and the second via structure V2 may be formed to have a width larger than a width of the via hole OH3 formed in the region corresponding to the third via structure V3.

In this case, as for the via holes OH3 formed in the first connection region CA1 and the second connection region CA2 corresponding to the first via structure V1 and the second via structure V2, the plurality of electrode layer 230, portions of the plurality of capacitor dielectric layer 220 and the first insulating layer 211 and the second insulating layer 225 may be simultaneously removed through laser etching by focusing on the first opening OH1 and the second opening OH2 in the first opening region S1 and the second opening region S2.

As described above, when the first via structure V1 and the second via structure V2 having a relatively larger width are etched, the first opening OH1 and the second opening OH2 may be formed preferentially, thereby preventing misaligned defects.

Thereafter, as illustrated in FIG. 12E, a diffusion barrier 241 or an ohmic contact layer 242 (see FIG. 9) may be formed on a side surface of the via holes OH3 and an upper surface of the second insulating layer 225. The diffusion barrier 241 or the ohmic contact layer 242 may function as a seed layer for electrolytic plating of the conductive material forming the via, but an example embodiment thereof is not limited thereto.

A preliminary conductive layer 250p may be further formed in and on the via hole OH3. The preliminary conductive layer 250p may be formed by over-plating the upper portion of the second insulating layer 225, and may also be formed by vapor deposition. When the preliminary conductive layer 250p is formed on the second insulating layer 225, by patterning the upper interconnection structure 240 together, the upper interconnection structure 240 and the via structures (e.g., the first via structure V1 and the second via structure V2), and V3 may be formed simultaneously. Thereafter, by forming the optical unit 170 on one surface of the substrate 101, the pixel array 10 in FIG. 5 may be formed.

According to the aforementioned example embodiments, by applying a MIM capacitor in the pixel circuit, a dynamic range may be improved. Also, sufficient capacitance may be assured by connecting stacked-type capacitors to each other in parallel.

Also, leakage current may occur as capacitance increases in the same area, but the risk of leakage may be reduced by disposing vias in the diagonal direction and maximizing the space between the vias. Also, by forming the via for the ground to be smaller than other vias and cutting corners of the capacitors to be spaced apart from the capacitor by a predetermined distance or more, the risk of leakage may be further reduced.

While non-limiting example embodiments have been described above with reference to the drawings, it will be apparent to those skilled in the art that modifications and variations may be made without departing from the spirit and scope of the present disclosure.

What is claimed is:

1. An image sensor, comprising:
a substrate comprising a plurality of photoelectric conversion regions to correspond to a plurality of pixels, respectively;
a plurality of capacitor structures on the substrate;
a capacitor insulating layer in a spacing between the plurality of capacitor structures; and
external via structures in the spacing between the plurality of capacitor structures and penetrating the capacitor insulating layer,
wherein each of the plurality of capacitor structures comprises:
conductive plate layers stacked and spaced apart from each other in a first direction perpendicular to an upper surface of the substrate;
capacitor dielectric layers alternately stacked with the conductive plate layers;
a first via structure penetrating the conductive plate layers, spaced apart from odd-numbered ones of the conductive plate layers in a positional order, and in lateral contact with even-numbered ones of the conductive plate layers in the positional order; and
a second via structure spaced apart from the first via structure, penetrating the conductive plate layers, spaced apart from the even-numbered ones of the conductive plate layers, and in lateral contact with the odd-numbered ones of the conductive plate layers, and
wherein, in a plane view, the external via structures, the first via structure, and the second via structure are disposed on extension lines of diagonals of the conductive plate layers.

2. The image sensor of claim 1, wherein a width of each of the external via structures is smaller than a width of the first via structure or a width of the second via structure.

3. The image sensor of claim 1, wherein corner regions of the conductive plate layers, adjacent to the external via structures, are chamfered.

4. The image sensor of claim 1, wherein, in the plane view, a first spacing distance between the first via structure and the second via structure is greater than a second spacing distance between each of the external via structures and the first via structure or the second via structure adjacent thereto on the extension lines of diagonals of the conductive plate layers.

5. The image sensor of claim 1,
wherein each of the plurality of capacitor structures comprises a first connection region penetrated by the first via structure and a second connection region penetrated by the second via structure, and
wherein the first via structure and the second via structure are spaced apart from each other on the diagonals of the conductive plate layers.

6. The image sensor of claim 5,
wherein a width of the first via structure and a width of the second via structure are the same as each other, and
wherein a width of the first connection region and a width of the second connection region are the same as each other.

7. The image sensor of claim 5,
wherein, in the first connection region, the odd-numbered ones of the conductive plate layers each comprise a first opening region, and
wherein, in the second connection region, the even-numbered ones of the conductive plate layers each comprise a second opening region.

8. The image sensor of claim 7,
wherein the even-numbered ones of the conductive plate layers cover the first opening region that is below the even-numbered ones of the conductive plate layers in the first connection region, and
wherein the odd-numbered ones of the conductive plate layers cover the second opening region that is below the odd-numbered ones of the conductive plate layers in the second connection region.

9. The image sensor of claim 7, wherein a width of the first opening region of each of the odd-numbered ones of the conductive plate layers is the same as each other, and a width of the second opening region of each of the even-numbered ones of the conductive plate layers are the same as each other.

10. The image sensor of claim 1, wherein each of the plurality of capacitor structures comprises:
a lower interconnection structure in a lower portion of each of the first via structure and the second via structure;
an upper interconnection structure in an upper portion of each of the first via structure and the second via structure; and
a first insulating layer between the lower interconnection structure and the conductive plate layers, and
wherein the capacitor insulating layer covers the conductive plate layers and is below the upper interconnection structure.

11. The image sensor of claim 10, wherein a thickness of at least one from among the lower interconnection structure and the upper interconnection structure is greater than a thickness of each of the conductive plate layers.

12. The image sensor of claim 1, wherein the conductive plate layers comprise metal or metal nitride.

13. The image sensor of claim 9, wherein the conductive plate layers comprise polysilicon.

14. An image sensor, comprising:
a substrate comprising a plurality of photoelectric conversion regions to correspond to a plurality of unit pixel areas, respectively;
interconnection structures on a first surface of the substrate and connected to the plurality of unit pixel areas;
a plurality of capacitor structures on the interconnection structures, on the first surface of the substrate, such as to correspond to the plurality of unit pixel areas, respectively;
a capacitor insulating layer in a spacing between the plurality of capacitor structures; and
color filters and microlenses stacked on a second surface of the substrate, opposite of the first surface,
wherein each of the plurality of capacitor structures comprises:
a stack structure comprising conductive plate layers stacked and spaced apart from each other in a first direction perpendicular to the first surface of the substrate, and capacitor dielectric layers alternately stacked with the conductive plate layers;
a first via structure penetrating the stack structure, spaced apart from odd-numbered ones of the conductive plate layers in a positional order, and in lateral contact with even-numbered ones of the conductive plate layers in the positional order; and
a second via structure spaced apart from the first via structure, penetrating the stack structure, spaced apart from the even-numbered ones of the conductive plate layers, and in lateral contact with the odd-numbered ones of the conductive plate layers, and
wherein the first via structure and the second via structure are disposed on diagonals of the conductive plate layers.

15. The image sensor of claim 14, wherein a center of each of the plurality of capacitor structures is offset with respect to a center of each of the plurality of unit pixel areas.

16. The image sensor of claim 14, further comprising:
a third via structure in the spacing between the plurality of capacitor structures, penetrating the capacitor insulating layer, and connected to at least one of the interconnection structures.

17. The image sensor of claim 16, wherein a width of the third via structure is smaller than widths of the first via structure and the second via structure.

18. The image sensor of claim 17, wherein the first via structure, the second via structure, and the third via structure are disposed linearly on extension lines of the diagonals of the conductive plate layers.

19. The image sensor of claim 17, wherein the interconnection structures comprise:
a lower interconnection structure between the substrate and the plurality of capacitor structures; and
an upper interconnection structure on the plurality of capacitor structures, and
wherein the lower interconnection structure and the upper interconnection structure are electrically connected to each other by the third via structure.

20. An image sensor, comprising:
a substrate;
a pixel array comprising a plurality of pixels arranged in a direction parallel to a first surface of the substrate, wherein each of the plurality of pixels comprises at least one photodiode in the substrate, a color filter on a second surface of the substrate opposite to the first surface, and at least one element on the first surface;
a plurality of capacitor structures on the substrate such as to correspond to the plurality of pixels, respectively;
a capacitor insulating layer in a spacing between the plurality of capacitor structures;
external via structures in the spacing between the plurality of capacitor structures and penetrating the capacitor insulating layer; and
a logic circuit configured to obtain a pixel signal from the plurality of pixels,
wherein each of the plurality of capacitor structures comprises:
conductive plate layers stacked and spaced apart from each other in a first direction perpendicular to the first surface of the substrate;
capacitor dielectric layers alternately stacked with the conductive plate layers;
a first via structure penetrating the conductive plate layers, spaced apart from odd-numbered ones of the conductive plate layers in a positional order, and in lateral contact with even-numbered ones of the conductive plate layers in the positional order; and
a second via structure spaced apart from the first via structure, penetrating the conductive plate layers, spaced apart from the even-numbered ones of the conductive plate layers, and in lateral contact with the odd-numbered ones of the conductive plate layers, and
wherein, in a plane view, the external via structures, the first via structure, and the second via structure are disposed on extension lines of diagonals of the conductive plate layers.
